(19) United States
(12) Patent Application Publication
(10) Pub. No.: US 2016/0268553 A1
(43) Pub. Date: Sep. 15, 2016

(54) NANOSTRUCTURES FOR OLED DEVICES

(71) Applicant: 3M INNOVATIVE PROPERTIES COMPANY, St. Paul, MI (US)

(72) Inventors: Michael Benton Free, St. Paul, MN (US); Martin B. Wolk, Woodbury, MN (US); Sergey Lamansky, Redmond, WA (US); Olester Benson, Jr., Woodbury, MN (US)

(21) Appl. No.: 15/033,932

(22) PCT Filed: Oct. 20, 2014
(86) PCT No.: PCT/US14/61352

§ 371 Date: May 3, 2016

Related U.S. Application Data
(60) Provisional application No. 61/902,437, filed on Nov. 11, 2013.

(51) Int. Cl. H01L 51/52; H01L 51/56

(52) U.S. Cl. CPC H01L 51/5275; H01L 51/56; H01L 2251/5369; H01L 27/3244

(57) ABSTRACT

The present disclosure describes method of using nanostructured lamination transfer films for the fabrication of an OLED having a nanostructured solid surface, using lamination techniques. The methods involve transfer and/or replication of a film, layer, or coating in order to form a nanostructured surface directly on a photosensitive optical coupling layer (pOCL) that is in contact with the emitting surface of an OLED in, for example, a top emitting active matrix OLED (AMOLED) device. The pOCL layer is subsequently cured to form an optical coupling layer (OCL) and the nanostructured film tool removed to result in a nanostructured OLED.

### BACKGROUND

Nanostructures and microstructures are used for a variety of applications in display, lighting, architecture and photovoltaic devices. In display devices including organic light emitting diode (OLED) devices, the structures can be used for light extraction or light distribution. In lighting devices the structures can be used for light extraction, light distribution, and decorative effects. In photovoltaic devices the structures can be used for solar concentration and antireflection. Patterning or otherwise forming nanostructures and microstructures on large substrates can be difficult and not cost-effective.

### SUMMARY

The present disclosure describes method of using nanostructured lamination transfer films for the fabrication of an OLED having a nanostructured solid surface, using lamination techniques. The methods involve transfer and/or replication of a film, layer, or coating in order to form a nanostructured surface directly on a photosensitive optical coupling layer (pOCL) that is in contact with the emitting surface of an OLED in, for example, a top emitting active matrix OLED (AMOLED) device. The pOCL layer is subsequently cured to form an optical coupling layer (OCL) and the nanostructured film tool removed to result in a nanostructured OLED. In one aspect, the present disclosure provides an image display that includes at least one OLED having a top surface; and a high index optical coupling layer (OCL) in contact with the top surface, the high index optical coupling layer having a nanostructured exterior surface.

In another aspect, the present disclosure provides a method that includes coating an optical coupling layer (OCL) precursor on a top surface of an OLED array, forming a planarized OCL precursor surface; laminating a template film having a nanostructured surface onto the OCL precursor surface such that the OCL precursor at least partially fills the nanostructured surface; polymerizing the OCL precursor to form a nanostructured OCL; and removing the template film.

In yet another aspect, the present disclosure provides a method that includes coating an optical coupling layer (OCL) precursor on a top surface of an OLED array, forming a planarized OCL precursor surface; laminating a template film onto the OCL precursor surface such that a planar outer surface of the transfer layer of the template film contacts the OCL precursor surface, wherein the transfer layer includes an embedded nanostructured surface; polymerizing the OCL precursor to form the OCL and bonding the planar outer surface of the transfer layer to the OCL; and removing the template film from the transfer layer.

In yet another aspect, the present disclosure provides a method that includes coating an optical coupling layer (OCL) precursor on a nanostructured surface of a template film; laminating the template film onto a major surface of an OLED array such that the OCL precursor contacts the major surface; polymerizing the OCL precursor to form the OCL and bond the OCL to the major surface of the OLED array; and removing the template film.

In yet another aspect, the present disclosure provides a method that includes forming a nanostructured layer on a nanostructured surface of a template film such that the nanostructured layer has a planar outer surface and an embedded nanostructured surface; coating an optical coupling layer (OCL) precursor on the planar outer surface to form a transfer film; laminating the transfer film onto a major surface of an OLED array such that the OCL precursor contacts the major surface; polymerizing the OCL precursor to form the OCL and bond the OCL to the major surface of the OLED array; and removing the template film from the nanostructured layer.

In yet another aspect, the present disclosure provides a method that includes coating an optical coupling layer (OCL) precursor on a top surface of an OLED array, forming a planarized OCL precursor surface; laminating a template film having a nanostructured surface onto the planarized OCL precursor surface such that the OCL precursor at least partially fills the nanostructured surface; polymerizing the OCL precursor in selected regions to form a patterned nanostructured OCL having unpolymerized regions; removing the template film; and polymerizing the unpolymerized regions.

In yet another aspect, the present disclosure provides a method that includes coating an optical coupling layer (OCL) precursor on a top surface of an OLED array, forming a planarized OCL precursor surface; masking selected regions of the OCL precursor to prevent polymerization; polymerizing the OCL precursor to form a patterned OCL having unpolymerized regions; laminating a transfer film onto the patterned OCL such that a transfer layer of the transfer film contacts a major surface of the patterned OCL, wherein the transfer layer includes a planar outer surface and an embedded nanostructured surface; removing the transfer film from the patterned OCL, leaving the transfer layer in the selected regions; and polymerizing the unpolymerized regions of the patterned OCL to bond the planar outer transfer layer to the selected regions of the OCL.

In yet another aspect, the present disclosure provides a method that includes forming a transfer layer on a nanostructured surface of a transfer film such that the transfer layer has a planar outer surface and an embedded nanostructured surface; coating an optical coupling layer (OCL) precursor on the planar outer surface; masking selected regions of the OCL precursor to prevent polymerization; polymerizing the OCL precursor to form a patterned OCL having unpolymerized transferable OCL regions; laminating the transfer film onto a major surface of an OLED array such that the unpolymerized transferable OCL regions contact the major surface; polymerizing the unpolymerized transferable OCL regions to form a bonded patterned nanostructured OCL on the major surface of the OLED array; and removing the transfer film from the major surface of the OLED array, leaving the bonded patterned nanostructured OCL on the major surface of the OLED array.

The above summary is not intended to describe each disclosed embodiment or every implementation of the present disclosure. The figures and the detailed description below more particularly exemplify illustrative embodiments.

### BRIEF DESCRIPTION OF THE DRAWINGS

Throughout the specification reference is made to the appended drawings, where like reference numerals designate like elements, and wherein:

FIG. 1 shows a schematic cross-section view of portion of a nanostructured AMOLED device;

FIGS. 2A-2B show a schematic cross-section view of known AMOLEDs with nanostructures;

FIG. 3 shows a method for making a nanostructured AMOLED device;

FIG. 4 shows a method for making a nanostructured AMOLED device;

FIG. 5 shows a method for making a nanostructured AMOLED device;

FIG. 6 shows a method for making a nanostructured AMOLED device;

FIG. 7 shows a method for making a nanostructured AMOLED device;

FIG. 8 shows a method for making a nanostructured AMOLED device;

FIG. 9 shows a method for making a nanostructured AMOLED device; and

FIG. 10 shows a method for making a nanostructured AMOLED device.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

The present disclosure describes a technique of using structured lamination transfer films, such as nanostructured lamination transfer films, for the fabrication of an organic light emitting diode (OLED) having a structured solid surface, using lamination techniques. In some cases, the structured solid surface can be a nanostructured solid surface, having surface features on a size scale less than about 2 microns. The methods involve transfer and/or replication of a film, layer, or coating in order to form a nanostructured surface directly on a photosensitive optical coupling layer (pOCL) in contact with the emitting surface of an OLED in, for example, a top emitting active matrix OLED (AMOLED) device. The pOCL layer is subsequently cured to form an optical coupling layer (OCL) and the transfer film removed to result in a nanostructured OLED that exhibits improved outcoupling of light emitted from the device and in a thin, easy to fabricate design. One particular advantage of the described methods is that it allows nanopatterning of a finished device without the solvent steps that can be required for traditional photolithographic patterning of nanostructures, including, for example, resist coating, resist developing, and resist stripping steps.

In the following description, reference is made to the accompanying drawings that forms a part hereof and in which are shown by way of illustration. It is to be understood that other embodiments are contemplated and may be made without departing from the scope or spirit of the present disclosure. The following detailed description, therefore, is not to be taken in a limiting sense.

All scientific and technical terms used herein have meanings commonly used in the art unless otherwise specified. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “lower,” “upper,” “beneath,” “below,” “above,” and “on top,” if used herein, are utilized for ease of description to describe spatial relationships of an element(s) to another. Such spatially related terms encompass different orientations of the device in use or operation in addition to the particular orientations depicted in the figures and described herein. For example, if an object depicted in the figures is turned over or flipped over, portions previously described as below or beneath other elements would then be above those other elements.

As used herein, when an element, component or layer for example is described as forming a “coincident interface” with, or being “on” “connected to,” “coupled with” or “in contact with” another element, component or layer, it can be directly on, directly connected to, directly coupled with, in direct contact with, or intervening elements, components or layers may be on, connected, coupled or in contact with the particular element, component or layer, for example. When an element, component or layer for example is referred to as being “directly on,” “directly connected to,” “directly coupled with,” or “directly in contact with” another element, there are no intervening elements, components or layers for example.

As used herein, “have”, “having”, “include”, “including”, “comprise”, “comprising” or the like are used in their open ended sense, and generally mean “including, but not limited to.” It will be understood that the terms “consisting of” and “consisting essentially of” are subsumed in the term “comprising,” and the like.

The term “OLED” refers to an organic light emitting device. OLED devices include a thin film of electroluminescent organic material sandwiched between a cathode and an anode, with one or both of these electrodes being a transparent conductor. When a voltage is applied across the device, electrons and holes are injected from their respective electrodes and recombine in the electroluminescent organic material through the intermediate formation of emissive excitons. The term “AMOLED” refers to an active matrix OLED, and the techniques described herein can generally be applied to both OLED devices and AMOLED devices.

A “structured optical film” refers to a film or layer that improves light outcoupling from an OLED device and/or improves angular luminance or/and color uniformity of the OLED. The light extraction function and angular luminance/color improvement function can also be combined in one structured film. A structured optical film can include periodic, quasi-periodic or random engineered nanostructures (e.g., light extraction film, described below), and/or it can include periodic, quasi-periodic or random engineered microstructures with structured feature size of equal or higher than 1 um.

The terms “nanostructure” or “nanostructures” refers to structures having at least one dimension (e.g., height, length, width, or diameter) of less than 2 micrometers and more preferably less than one micrometer. Nanostructure includes, but is not necessarily limited to, particles and engineered features. The particles and engineered features can have, for example, a regular or irregular shape. Such particles are also referred to as nanoparticles. The term “nanostructured” refers to a material or layer having nanostructures, and the term “nanostructured AMOLED device” means an AMOLED device that incorporates nanostructures.

The term “actinic radiation” refers to wavelengths of radiation that can crosslink or cure polymers and can include ultraviolet, visible, and infrared wavelengths and can include digital exposures from rastered lasers, thermal digital imaging, and electron beam scanning.

Nanostructured lamination transfer films and methods are described that enable the fabrication of OLEDs having nanostructured solid surfaces, using lamination techniques. The methods involve transfer and/or replication of a film, layer, or coating in order to form a nanostructured optical coupling layer (OCL) designed to improve light extraction efficiency from emissive devices. Lamination transfer films, patterned structured tapes, and methods of using nanostructured tapes useful in the present disclosure have been described, for example, in Applicants' pending applications, U.S. patent application Ser. No. 13/553,987, entitled STRUCTURED LAMINATION TRANSFER FILMS AND METHODS, filed Jul. 20, 2012; Ser. No. 13/723,716, entitled PATTERNED STRUCTURED TRANSFER TAPE, filed Dec. 21, 2012; and Ser. No. 13/723,675, entitled METHODS OF USING NANOSTRUCTURED TRANSFER TAPE AND ARTICLES MADE THEREFROM, filed Dec. 21, 2012.

In some embodiments, a photocurable prepolymer solution, typically photocurable upon exposure to actinic radiation (typically ultraviolet radiation) can be cast against a microreplicated master and then exposed to actinic radiation while in contact with the microreplicated master to form the template layer. The photocurable prepolymer solution can be cast onto the surface of an OLED device before, during, and even sometimes after, being photopolymerized while in contact with a microreplicated master.

The structured optical film or a non-polarization preserving element described herein can be a separate film applied to an OLED device. For example, an optical coupling layer (OCL) can be used to optically couple the structured optical film or a non-polarization preserving element to a light output surface of an OLED device. The optical coupling layer can be applied to the structured optical film or a non-polarization preserving element, the OLED device, or both, and it can be implemented with an adhesive to facilitate application of the structured optical film or a non-polarization preserving element to the OLED device. Examples of optical coupling layers and processes for using them to laminate light extraction films to OLED devices are described in U.S. patent application Ser. No. 13/050,324, entitled OLED LIGHT EXTRACTION FILMS HAVING NANOPARTICLES AND PERIODIC STRUCTURES and filed Mar. 17, 2011, which is incorporated herein by reference as if fully set forth.

The Optical Coupling Material/layer can be used as an interlayer/“adhesive” between OLED devices and extraction elements (nanoparticles and periodic structure). It can help in out-coupling light modes from the light source (OLEDs) to the nano-structured film to enhance light output. The materials for optical coupling layer preferably have a high index of refraction, at least 1.65 or 1.70 or even up to 2.2, comparable to that of OLED organic and inorganic layers (e.g., ITO). The OCL can be optionally cured using UV or thermal curing methods, although UV curing can be preferred. The material could be 100 percent pure resin such as, for example a high refractive index Acryl Resin #6205 having n>1.7 (available from NTT Advanced Technology, Tokyo, JP) or a mixture of surface modified high index particles (TiO2 or ZrO2) dispersed in a resin system such as that described in U.S. Patent Publication 2002/0329959.

The nanostructures for the structured optical film or a non-polarization preserving element (e.g., light extraction film) can be formed integrally with the substrate or in a layer applied to the substrate. For example, the nanostructures can be formed on the substrate by applying to the substrate a material and subsequently structuring the material. Nanostructures are structures having at least one dimension, such as width, less than about 2 microns, or even less than about 1 micron.

Nanostructure includes, but is not necessarily limited to, particles and engineered features. The particles and engineered features can have, for example, a regular or irregular shape. Such particles are also referred to as nanoparticles. Engineered nanostructures are not individual particles but may comprise nanoparticles forming the engineered nanostructures where the nanoparticles are significantly smaller than the overall size of the engineered structures.

The nanostructures for a structured optical film or a non-polarization preserving element (e.g., light extraction film) can be one-dimensional (1D), meaning they are periodic in only one dimension, that is, nearest-neighbor features are spaced equally in one direction along the surface, but not along the orthogonal direction. In the case of 1D periodic nanostructures, the spacing between adjacent periodic features is less than 2 microns and can even be less than 1 micron. One-dimensional structures include, for example, continuous or elongated prisms or ridges, or linear gratings.

The nanostructures for a structured optical film or a non-polarization preserving element (e.g., light extraction film) can also be two-dimensional (2D), meaning they are periodic in two dimensions, that is, nearest neighbor features are spaced equally in two different directions along the surface. In the case of 2D nanostructures, the spacing in both directions is less than 1 micron. Note that the spacing in the two different directions may be different. Two-dimensional structures include, for example, diffractive optical structures, pyramids, trapezoids, round or square shaped posts, or photonic crystal structures. Other examples of two-dimensional structures include curved sided cone structures as described in U.S. Pat. Application Publication No. 2010/0128351, which is incorporated herein by reference as if fully set forth.

Materials for the substrates, multi-periodic structures, and transfer layers for light extraction film are provided in the published patent applications identified above. For example, the substrate can be implemented with glass, PET, polyimides, TAC, PC, polyurethane, PVC, or flexible glass. Processes for making light extraction film are also provided in the published patent applications identified above. Optionally, the substrate can be implemented with a barrier film to protect a device incorporating the light extraction film from moisture or oxygen. Examples of barrier films are disclosed in U.S. Patent Publication No. 2007/0020451 and U.S. Pat. No. 7,468,211, both of which are incorporated herein by reference as if fully set forth.

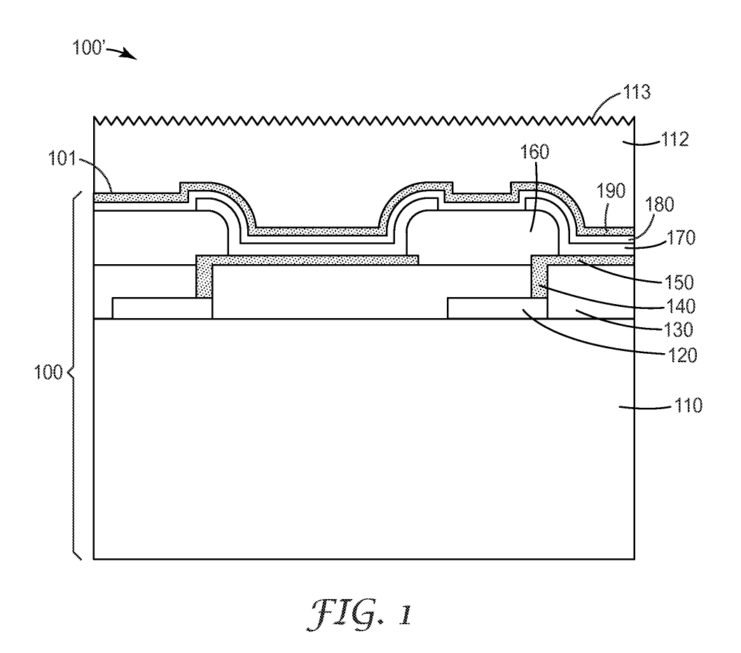

FIG. 1 shows a schematic cross-section view of portion of a nanostructured AMOLED device 100′, according to one aspect of the disclosure. The nanostructured AMOLED device 100′ can be top-emitting, bottom emitting, or it can be both top- and bottom-emitting; however, for the purposes of the present disclosure, a top-emitting AMOLED having light extraction nanostructures suitable for top-emitting AMOLEDs is described. It is to be understood that adaptation of the present disclosure to bottom-emitting devices can be made by performing the process techniques for application of light extraction nanostructures to other surfaces within the device.

The nanostructured AMOLED device 100′ includes an AMOLED 100 having an OLED support 110, pixel circuitry 120 disposed on the support, and a pixel circuit planarization layer 130 initially deposited covering the entire support and pixel circuitry, as known to those of skill in the art. AMOLED 100 further includes at least one via 140 passing through the pixel circuit planarization layer 130 providing an electrical connection to at least one bottom electrode 150 deposited over a portion of the planarization layer. A pixel defining layer 160 is deposited over the pixel circuit planarization layer 130 and a portion of each bottom electrode 150 to define and electrically isolate individual pixels. An OLED 170 having a plurality of known layers (not shown) is deposited over the bottom electrode 150 and a portion of the pixel defining layer 160, a transparent top electrode 180 is deposited over the OLED 170 and pixel defining layer 160, and a thin film encapsulation layer 190 is deposited to protect the moisture and oxygen sensitive device from the environment and also from any subsequent processing steps. A polymeric optical coupling layer (OCL) 112 including a light extraction nanostructured surface 113 can be disposed on a top surface 101 of the AMOLED 100 (i.e., on top of the thin film encapsulation layer 190) to result in the nanostructured AMOLED device 100′, as described elsewhere.

In one particular embodiment, OLED extraction structures may be used to control the light distribution pattern of the device. OLEDs lacking a microcavity in the OLED optical stack may be Lambertian emitters, with a light distribution pattern that is smooth and evenly distributed over a hemisphere. However, the light distribution pattern of commercially available AMOLED displays usually exhibit characteristics of a microcavity in the optical stack. These characteristics include a narrower and less uniform angular light distribution and significant angular color variation. For OLED displays, it may be desirable to tailor the light distribution with nanostructures, using the methods disclosed herein. The nanostructures may function to improve light extraction, to redistribute the emitted light, or both. Structures can also be useful on the external surface of an OLED substrate to extract light into air that is trapped in substrate total internal reflection modes. External extraction structures can include microlens arrays, microfresnel arrays, or other refractive, diffractive, or hybrid optical elements.

The AMOLED 100 can be a receptor substrate for the OCL 112, and formed of organic semiconductor materials on a support, such as a support wafer. The dimensions of these receptor substrates can exceed those of a semiconductor wafer master template. Currently, the largest wafers in production have a diameter of 300 mm. Lamination transfer films produced using the method disclosed herein can be made with a lateral dimension of greater than 1000 mm and a roll length of hundreds of meters. In some embodiments, the receptor substrates can have dimensions of about 620 mm×about 750 mm, of about 680 mm×about 880 mm, of about 1100 mm×about 1300 mm, of about 1300 mm×about 1500 mm, of about 1500 mm×about 1850 mm, of about 1950 mm×about 2250 mm, or about 2200 mm×about 2500 mm, or even larger. For long roll lengths, the lateral dimensions can be greater than about 750 mm, greater than about 880 mm, greater than about 1300 mm, greater than about 1500 mm, greater than about 1850 mm, greater than about 2250 nm, or even greater than about 2500 mm. Typical dimensions have a maximum patterned width of about 1400 mm. The large dimensions are possible by using a combination of roll-to-roll processing and a cylindrical master template. Films with these dimensions can be used to impart nanostructures over entire large digital displays (e.g., a 55 inch diagonal AMOLED HDTV, with dimensions of 52 inches wide by 31.4 inches tall).

The receptor substrate can optionally include a buffer layer on a side of the receptor substrate to which a lamination transfer film is applied. Examples of buffer layers are disclosed in U.S. Pat. No. 6,396,079 (Hayashi et al.), which is incorporated herein by reference as if fully set forth. One type of buffer layer is a thin layer of SiO₂, as disclosed in K. Kondoh et al., J. of Non-Crystalline Solids 178 (1994) 189-98 and T-K. Kim et al., Mat. Res. Soc. Symp. Proc. Vol. 448 (1997) 419-23.

A particular advantage of the transfer process disclosed herein is the ability to impart structure to receptor surfaces with large surfaces, such as display mother glass or architectural glass. The dimensions of these receptor substrates exceed those of a semiconductor wafer master template. The large dimensions of the lamination transfer films are possible by using a combination of roll-to-roll processing and a cylindrical master template. An additional advantage of the transfer process disclosed herein is the ability to impart structure to receptor surface that are not planar. The receptor substrate can be curved, bent twisted, or have concave or convex features, due to the flexible format of the transfer tape. Receptor substrates may include, for example, automotive glass, sheet glass, flexible electronic substrates such as circuitized flexible film, display backplanes, solar glass, metal, polymers, polymer composites, and fiberglass.

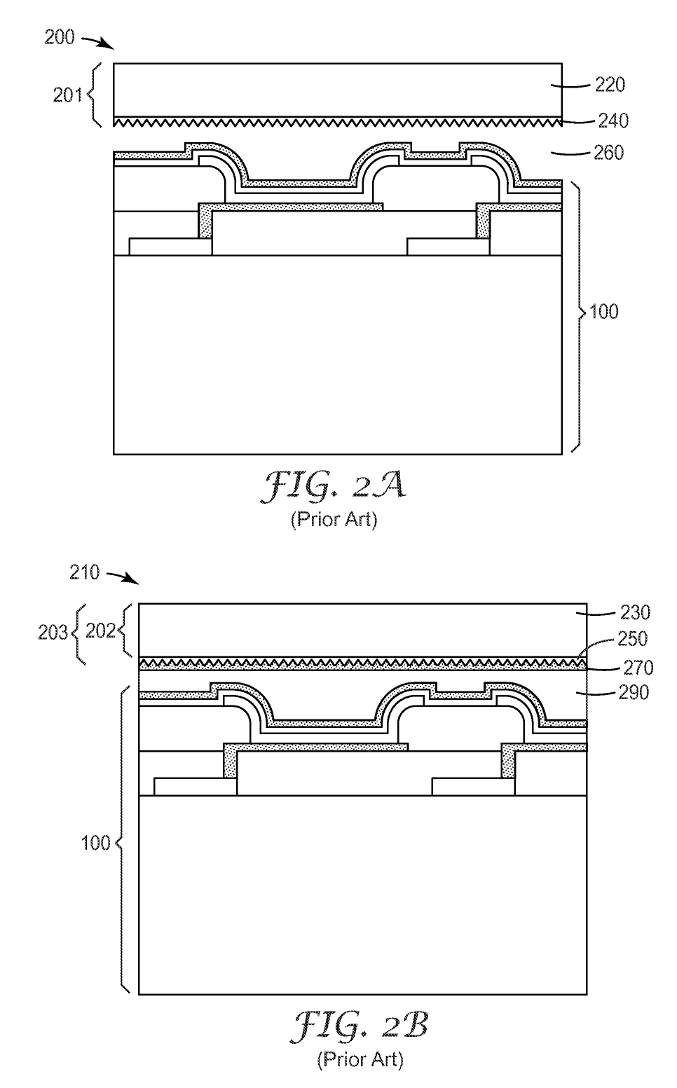

FIGS. 2A-2B shows a schematic cross-section view of known AMOLED devices 100 having associated nanostructures, according to one aspect of the disclosure. In FIG. 2A, an uncoupled AMOLED device 200 includes the AMOLED device 100 of FIG. 1 and a nanostructured film 201 having a support film 220 and a nanostructure 240 disposed on a major surface of the support film 220. An air gap 260 separates the AMOLED device 100 from the nanostructure 240. Such uncoupled AMOLED devices 200 can be used to improve angular color performance of the device (i.e., increase wide-angle color), although there is no improvement in the efficient emission from the AMOLED device 100, and known problems with trapping light within the OLED structure are still present.

In FIG. 2B, a coupled AMOLED device 210 includes the AMOLED device 100 of FIG. 1 and a nanostructured film 202 having a support film 230 and a nanostructure 250 disposed on a major surface of the support film 230. A backfill layer 270 fills the nanostructure 250, and the backfill layer 270 is separated from the AMOLED device 100 by an optical coupling layer 290. The refractive index nₙₐₙₒ of the nanostructure 250 is less than the refractive index of the backfill (n_{back}) and the optical coupling layer (n_{ocl}), and as such, extraction of light from the AMOLED device 100 is enhanced. Proper selection of the various refractive indices couples light to be emitted from the OLED that would otherwise be trapped within the layers. Although the coupled AMOLED device 210 can exhibit improved efficiency of light extraction, the resulting thickness of the device, as well as the complexity and costs of assembly, have been impediments to the adoption of such improved devices.

Such prior techniques for incorporating nanostructured surface into OLED devices have problems which can be overcome by the present disclosure. These problems can include multiple replication/lamination steps, use of sacrificial layers, overall thickness of the resulting article, optical losses caused by index mismatch, diffusion in the film, thermal stability, water susceptibility, thickness, delamination, birefringence, scattering, and the like. Optically coupled OLED device 210 provides a nanostructured interface for extraction as well as a polymer support film. The polymer support film provides no benefit to device performance, and may indirectly introduce mechanical, chemical, and optical factors that are, in fact, detrimental to device performance. In some cases, the relatively stiff film may buckle or delaminate over time and the film thickness will contribute to the overall thickness of the device. In some cases, the film may serve as a reservoir for moisture, oxygen, or other small molecules (e.g. plasticizers) that may migrate to the OLED device layers and degrade performance. In some cases, the film may degrade the optical performance of the device by introducing reflections at interfaces, scattering from the bulk of the film, or reducing efficacy of a externally laminated circular polarizer with residual birefringence.

Transfer Layer and pOCL Materials

A transfer layer can be used to fill the nanostructured template, and is a material capable of substantially planarizing the adjacent layer (e.g., the template layer) while also conforming to the surface of the receptor layer. In some cases, the transfer layer can be more accurately described as being the nanostructured transfer layer, although structures other than those on a nanometer scale may be included. The materials used in the transfer layer can also be used as the pOCL materials that are photosensitive OCL precursors, as described elsewhere. The transfer layer can alternatively be a bilayer of two different materials where the bilayer has a multi-layer structure or where one of the materials is at least partially embedded in the other material. The two materials for the bilayer can optionally have different indices of refraction. One of the bilayers can optionally comprise an adhesion promoting layer.

In some embodiments, it can be preferable for the pOCL to substantially planarize the surface of the OLED. In other embodiments, it is preferable for the transfer layer to substantially planarize the surface of the nanostructured template film. Substantial planarization means that the amount of planarization (P %), as defined by Equation (1), is preferably greater than 50%, more preferably greater than 75%, and most preferably greater than 90%.

P %=(1−(t₁/h₁))*100 Equation (1)

where t₁ is the relief height of a surface layer and h₁ is the feature height of features covered by the surface layer, as further disclosed in P. Chiniwalla, IEEE Trans. Adv. Packaging 24 (1), 2001, 41.

Materials that may be used for the transfer layer include polysiloxane resins, polysilazanes, polyimides, silsesquioxanes of bridge or ladder-type, silicones, and silicone hybrid materials and many others. Exemplary polysiloxane resins include PERMANEW 6000 L510-1, available from California Hardcoat, Chula Vista, Calif. These molecules typically have an inorganic component which leads to high dimensional stability, mechanical strength, and chemical resistance, and an organic component that helps with solubility and reactivity. There are many commercial sources of these materials, which are summarized in Table 1 below. Other classes of materials that may be of use are benzocyclobutenes, soluble polyimides, and polysilazane resins, for example. Exemplary polysilazane resins include very low and low temperature cure inorganic polysilazanes such as NAX120 and NL 120A inorganic polysilazanes, available from AZ Electronic Materials, Branchburg, N.J.

The transfer layer can comprise any material as long as it has the desired rheological and physical properties discussed previously. Typically, the transfer layer is made from a polymerizable composition comprising monomers which are cured using actinic radiation, e.g., visible light, ultraviolet radiation, electron beam radiation, heat and combinations thereof. Any of a variety of polymerization techniques, such as anionic, cationic, free radical, condensation or others may be used, and these reactions may be catalyzed using photo, photochemical or thermal initiation. These initiation strategies may impose thickness restrictions on the transfer layer, i.e the photo or thermal trigger must be able to uniformly react throughout the entire film volume. Useful polymerizable compositions comprise functional groups known in the art, such as epoxide, episulfide, vinyl, hydroxyl, allyloxy, (meth)acrylate, isocyanate, cyanoester, acetoxy, (meth)acrylamide, thiol, silanol, carboxylic acid, amino, vinyl ether, phenolic, aldehyde, alkyl halide, cinnamate, azide, aziridine, alkene, carbamates, imide, amide, alkyne, and any derivatives or combinations of these groups. The monomers used to prepare the transfer layer can comprise polymerizable oligomers or copolymers of any suitable molecular weight such as urethane(meth)acrylates, epoxy(meth)acrylates, polyester(meth)acrylates) and the like. The reactions generally lead to the formation of a three-dimensional macromolecular network and are known in the art as negative-tone photoresists, as reviewed by Shaw et al., “Negative photoresists for optical lithography”, IBM Journal of Research and Development (1997) 41, 81-94. The formation of the network may occur through either through covalent, ionic, or hydrogen bonding or through physical crosslinking mechanisms such as chain entanglement. The reactions can also be initiated through one or more intermediate species, such as free-radical initiators, photosensitizers, photoacid generators, photobase generators, or thermal acid generators. Other molecular species may be involved in network formation as well, such as crosslinker molecules containing two or more functional groups known in the art to be reactive with the previously mentioned molecular species.

Reinforced silicone polymers can be used for the transfer layer, due to their high chemical stability and excellent adhesion to glasses such as float glass and borosilicate glass, and also some inorganic oxides such as, for example, molybdenum oxide which may be used as an OLED capping layer. Silicones are also well known not to adhere to other polymers, which makes this material straightforward to release from microstructured polymer tools, but difficult to transfer as one component in a dyad, unless the other component is also a silicone. One such silicone formulation, is known as SYLGARD 184 (Dow Corning, Midland, Mich.), which is a 2-component mixture of polydimethylsiloxane and vinylsiloxane mixed with hydrosiloxane and a platinum catalyst. Slight heating of this mixture causes the silicone network to form via platinum-catalyzed hydrosilylation curing reaction. Other silicones and catalysts can be used to the same effect. Gelest Inc. (Morrisville, Pa.) manufactures a wide variety of siloxanes functionalized with various reactive groups (epoxy, carbinol, mercapto, methacryloxy amino, silanol) for example. Gelest also sells these siloxanes pre-compounded with various additives, such as fully condensed silica nanoparticles or MQ resins, to tune the mechanical properties of the silicone network. Other platinum catalysts can also be used, such as (trimethyl) methyl cyclopentadenyl platinum (IV) (Strem Chemicals Inc., Newburyport, Mass.), which activates via ultraviolet radiation but still requires a subsequent thermal cure. Photocurable silicone systems are advantageous because as long as they are kept in the dark, their viscosity decreases with increasing temperature, allowing bubbles to escape and better penetration into nanostructured tools.

Different varieties of the above materials can be synthesized with higher refractive index by incorporating nanoparticles or metal oxide precursors in with the polymer resin. Silecs SC850 material is a modified silsesquioxane (n≈1.85) and Brewer Science high index polyimide OptiNDEX D1 material (n≈1.8) are examples in this category. Other materials include a copolymer of methyltrimethoxysilane (MTMS) and bistriethoxysilylethane (BTSE) (Ro et. al, Adv. Mater. 2007, 19, 705-710). This synthesis forms readily soluble polymers with very small, bridged cyclic cages of silsesquioxane. This flexible structure leads to increased packing density and mechanical strength of the coating. The ratio of these copolymers can be tuned for very low coefficient of thermal expansion, low porosity and high modulus.

In some embodiments, the transfer layer can include polyvinyl silsesquioxane polymers. These polymers can be prepared by the hydrolysis of vinyltriethoxysilane (I).

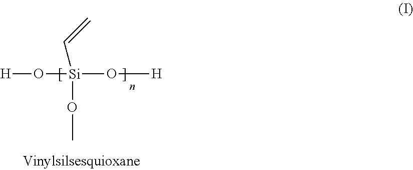

Upon polymerization, typically by the addition of a photoinitiator followed by exposure to ultraviolet radiation, a three dimensional network is formed by free radical polymerization of the many vinyl groups.

The transfer layer material typically can meet several requirements. First, it can conform to the structured surface of the template layer on which it is coated. This means that the viscosity of the coating solution should be low enough to be able to flow into very small features without the entrapment of air bubbles, which will lead to good fidelity of the replicated structure. If it is solvent based, it should be coated from a solvent that does not dissolve or swell the underlying template layer, which would cause cracking, swelling, or other detrimental defects of the transfer layer. It is desirable that the solvent has a boiling point below that of the template layer glass transition temperature. Preferably, isopropanol, butyl alcohol and other alcoholic solvents have been used. Second, the material should cure with sufficient mechanical integrity (e.g., “green strength”). If the transfer layer material does not have enough green strength after curing, the transfer layer pattern features can slump and the replication fidelity can degrade. Third, for some embodiments, the refractive index of the cured material should be tailored to produce the proper optical effect. Fourth, the transfer layer material should be thermally stable (e.g., showing minimal cracking, blistering, or popping) above the temperature of the upper range of the future process steps of the substrate. Typically the materials used for this layer undergo a condensation curing step, which causes shrinkage and the build-up of compressive stresses within the coating. There are a few materials strategies which are used to minimize the formation of these residual stresses which have been put to use in several commercial coatings which satisfy all of the above criteria.

It can be advantageous to adjust the refractive index of both the transfer layer and OCL layers. For example, in OLED light extraction applications, the nanostructure imparted by the transfer film is located at a structured surface of the transfer layer. The transfer layer has a first side at the structured interface and a second side coincident with an adjacent layer, the OCL. In this application, the refractive index of the transfer layer can be index matched to the OCL layer.

Nanoparticles can be used to adjust refractive index of the transfer and OCL layers. For example, in acrylic coatings, silica nanoparticles (n≈1.42) can be used to decrease refractive index, while zirconia nanoparticles (n≈2.1) can be used to increase the refractive index. If the index difference is large between the nanoparticles and binder, a haze will develop inside the bulk of the coating. For applications in which haze is a desirable attribute (e.g., uniform light distribution in OLED solid state lighting elements) the index matching criteria can be generally relaxed. Control over the relative index of the nanoparticles and binder provide control over the resulting optical properties. There is also a limit to the concentration of nanoparticles in the resin before particle aggregation begins to occur, thereby limiting the extent to which refractive index of the coating can be tuned.

TABLE 1
Thermally Stable Transfer Materials of Low and High Refractive Index

| Material Name or Trade | | |
|---|---|---|
| Designation | Type | Available from |
| TecheGlas GRx resins | T-resin (methyl | TechneGlas (Perrysburg, |
| | silsesquioxane) | Ohio) |
| HSG-510 | T-resin (methyl | Hitachi Chemical (Tokyo, |
| | silsesquioxane) | Japan) |
| ACCUGLASS 211 | T-Q resin (methyl | Honeywell (Tempe, AZ) |
| | silsesquioxane) | |
| HARDSIL AM | silica nanocomposite | Gelest Inc (Morrisville, PA) |
| MTMS-BTSE Copolymer | bridged silsesquioxane | National Institute of |
| (Ro et. al, Adv. Mater. 2007, | | Standards and Technology |
| 19, 705-710) | | (Gaithersburg, MD) |
| PERMANEW 6000 | silica-filled methyl- | California Hardcoat (Chula |
| | polysiloxane polymer | Vista, CA) |
| | containing a latent heat-cure | |
| | catalyst system | |
| FOX Flowable OXide | hydrogen silsesquioxane | Dow Corning (Midland, |
| | | MI) |
| ORMOCER, ORMOCLAD, | silicone hybrid | Micro Resist GmBH |
| ORMOCORE | | (Berlin, Germany) |
| SILECS SCx resins | silicone hybrid | Silecs Oy (Espoo, Finland) |
| | (n = 1.85) | |
| OPTINDEX D1 | soluble polyimide (n = 1.8) | Brewer Science (Rolla, |
| | | MO) |
| CORIN XLS resins | soluble polyimide | NeXolve Corp. (Huntsville, |
| | | AL) |
| CERASET resins | polysilazanes | KiON Specialty Polymers |
| | | (Charlotte, NC) |
| BOLTON metals | low melting metal | Bolton Metal Products |
| | | (Bellafonte, PA) |
| SYLGARD 184 | silicone network polymer | Dow Corning (Midland, |
| | | MI) |

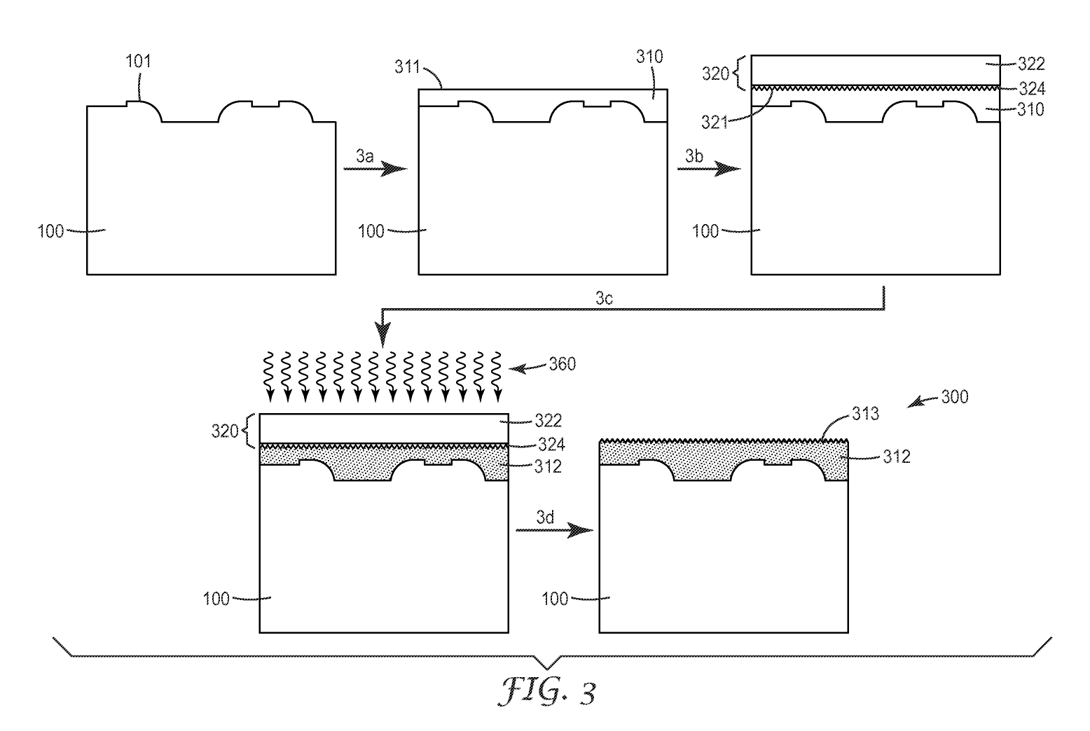

FIG. 3 shows a method for making a nanostructured AMOLED device 300, according to one aspect of the disclosure. The method for making a nanostructured AMOLED device 300 begins with an AMOLED 100 having a top surface 101, as described elsewhere with reference to FIG. 1. An optical coupling layer precursor (pOCL) 310 having a pOCL outer surface 311 is deposited on the top surface 101 (step 3a). As used herein, the optical coupling layer precursor (pOCL) can also be referred to as a photosensitive OCL, since in most cases, the optical coupling layer precursor generally can be cured to an optical coupling layer (OCL) through the use of visible or ultraviolet radiation curing. A nanostructured template film 320 having a nanostructured template layer 324 disposed on a support film 322 and coated with an optional release layer (not shown, as described below), is laminated to the pOCL 310 such that a nanostructured template layer surface 321 contacts the pOCL and the pOCL 310 flows to fill the nanostructured template layer surface 321 (step 3b). In one particular embodiment, nanostructured template film 320 can be provided on a release liner (not shown, as described elsewhere) that is removed prior to lamination, in order to protect the nanostructured template layer surface 321 during handling. Actinic radiation 360 is applied through the nanostructured template film 320, curing the pOCL 310 to become an optical coupling layer (OCL) 312 (step 3c). The nanostructured template film 320 can then be removed from the OCL 312, exposing the nanostructured extraction surface 313 and resulting in the nanostructured AMOLED device 300 (step 3d). The optional release layer, if provided, can be a thin layer of release coating (not shown) deposited by, in some cases, plasma enhanced chemical vapor deposition. Alternatively, other method of surface modification or coatings may be used to enhance the release properties of the structured template layer. In some embodiments, release properties may be inherent to the structured template layer, and the optional release layer may not be necessary, as described elsewhere.

### Support Film

The support film 322 can be any suitable film, including, for example, thermally stable flexible films that can provide mechanical support for the other layers. The support film 322 can be thermally stable above 50° C., or alternatively 70° C., or alternatively above 120° C. One example of a support film 322 is polyethylene terephthalate (PET). In some embodiments, the support film 322 can include paper, release-coated paper, non-wovens, wovens (fabric), metal films, and metal foils.

Various polymeric film substrates comprised of various thermosetting or thermoplastic polymers are suitable for use as the support film 322. The support may be a single layer or multi-layer film. Illustrative examples of polymers that may be employed as the support layer film include (1) fluorinated polymers such as poly(chlorotrifluoroethylene), poly(tetrafluoroethylene-cohexafluoropropylene), poly(tetrafluoroethylene-co-perfluoro(alkyl)vinylether), poly(vinylidene fluoride-cohexafluoropropylene); (2) ionomeric ethylene copolymers poly(ethylene-co-methacrylic acid) with sodium or zinc ions such as SURLYN-8920 Brand and SURLYN-9910 Brand available from E.I. duPont Nemours, Wilmington, Del.; (3) low density polyethylenes such as low density polyethylene; linear low density polyethylene; and very low density polyethylene; plasticized vinyl halide polymers such as plasticized poly(vinychloride); (4) polyethylene copolymers including acid functional polymers such as poly(ethylene-co-acrylic acid) “EAA”, poly(ethylene-co-methacrylic acid) “EMA”, poly(ethylene-co-maleic acid), and poly(ethylene-co-fumaric acid); acrylic functional polymers such as poly(ethylene-co-alkylacrylates) where the alkyl group is methyl, ethyl, propyl, butyl, et cetera, or CH3 (CH2)n- where n is 0 to 12, and poly(ethylene-co-vinylacetate) “EVA”; and (5) (e.g.) aliphatic polyurethanes. The support layer is typically an olefinic polymeric material, typically comprising at least 50 wt-% of an alkylene having 2 to 8 carbon atoms with ethylene and propylene being most commonly employed. Other body layers include for example poly(ethylene naphthalate), polycarbonate, poly(meth)acrylate (e.g., polymethyl methacrylate or “PMMA”), polyolefms (e.g., polypropylene or “PP”), polyesters (e.g., polyethylene terephthalate or “PET”), polyamides, polyimides, phenolic resins, cellulose diacetate, cellulose triacetate (TAC), polystyrene, styrene-acrylonitrile copolymers, cyclic olefin copolymers, epoxies, and the like.

### Nanostructured Template Layer

The nanostructured template layer 324 is the layer that imparts the structure to the pOCL or any other nanostructured transfer layer (not shown, described elsewhere) that is coated onto the nanostructured template layer 324. It is made up of template materials. The nanostructured template layer 324 can be formed through embossing, replication processes, extrusion, casting, or surface structuring, for example. It is to be understood that the nanostructured template layer 324 can generally be a template layer that can have a structured surface that may include nanostructures, microstructures, or hierarchical structures, although generally nanostructures are described herein. Nanostructures comprise features having at least one dimension (e.g., height, width, or length) less than or equal to one micron. Microstructures comprise features having at least one dimension (e.g., height, width, or length) less than or equal to one millimeter. Hierarchical structures are combinations of nanostructures and microstructures. In some embodiments, the template layer can be compatible with patterning, actinic patterning, embossing, extruding, and coextruding.

Typically, the template layer includes a photocurable material that can have a low viscosity during the replication process and then can be quickly cured to form a permanent crosslinked polymeric network “locking in” the replicated nanostructures, microstructures or hierarchical structures. Any photocurable resins known to those of ordinary skill in the art of photopolymerization can be used for the template layer. The resin used for the template layer must be capable, when crosslinked, of releasing from the transfer layer during the use of the disclosed structured tapes, or should be compatible with application of a release layer (see below) and the process for applying the release layer. Additionally, the resins used for the template layer preferably are compatible with the application of an adhesion promotion layer, as described elsewhere.

Polymers that can be used as the template layer also include the following: styrene acrylonitrile copolymers; styrene(meth)acrylate copolymers; polymethylmethacrylate; polycarbonate; styrene maleic anhydride copolymers; nucleated semi-crystalline polyesters; copolymers of polyethylenenaphthalate; polyimides; polyimide copolymers; polyetherimide; polystyrenes; syndiodactic polystyrene; polyphenylene oxides; cyclic olefin polymers; and copolymers of acrylonitrile, butadiene, and styrene. One preferable polymer is the Lustran SAN Sparkle material available from Ineos ABS (USA) Corporation. Polymers for radiation cured template layers include cross linked acrylates such as multifunctional acrylates or epoxies and acrylated urethanes blended with mono-and multifunctional monomers.

Patterned structured template layers can be formed by depositing a layer of a radiation curable composition onto one surface of a radiation transmissive support to provide a layer having an exposed surface, contacting a master with a preformed surface bearing a pattern capable of imparting a three-dimensional microstructure of precisely shaped and located interactive functional discontinuities including distal surface portions and adjacent depressed surface portions into the exposed surface of the layer of radiation curable composition on said support under sufficient contact pressure to impart said pattern into said layer, exposing said curable composition to a sufficient level of radiation through the carrier to cure said composition while the layer of radiation curable composition is in contact with the patterned surface of the master. This cast and cure process can be done in a continuous manner using a roll of support, depositing a layer of curable material onto the support, laminating the curable material against a master and curing the curable material using actinic radiation. The resulting roll of support with a patterned, structured template disposed thereon can then be rolled up. This method is disclosed, for example, in U.S. Pat. No. 6,858,253 (Williams et al.).

For extrusion or embossed template layers, the materials making up the template layer can be selected depending on the particular topography of the top structured surface that is to be imparted. In general, the materials are selected such that the structure is fully replicated before the materials solidify. This will depend in part on the temperature at which the material is held during the extrusion process and the temperature of the tool used to impart the top structured surface, as well as on the speed at which extrusion is being carried out. Typically, the extrudable polymer used in the top layer has a T_{g} of less than about 140° C., or a T_{g} of from about 85° C. to about 120° C., in order to be amenable to extrusion replication and embossing under most operating conditions. In some embodiments, the support film and the template layer can be coextruded at the same time. This embodiment requires at least two layers of coextrusion—a top layer with one polymer and a bottom layer with another polymer. If the top layer comprises a first extrudable polymer, then the first extrudable polymer can have a T_{g} of less than about 140° C. or a T_{g} or of from about 85° C. to about 120° C. If the top layer comprises a second extrudable polymer, then the second extrudable polymer, which can function as the support layer, has a T_{g} of less than about 140° C. or a T_{g} of from about 85° C. to about 120° C. Other properties such as molecular weight and melt viscosity should also be considered and will depend upon the particular polymer or polymers used. The materials used in the template layer should also be selected so that they provide good adhesion to the support so that delamination of the two layers is minimized during the lifetime of the optical article.

The extruded or coextruded template layer can be cast onto a master roll that can impart patterned structure to the template layer. This can be done batch-wise or in a continuous roll-to-roll process. Additionally, a nanostructured transfer layer can be extruded onto the extruded or coextruded template layer. In some embodiments, all three layers—support, template, and nanostructured transfer layers can be coextruded at once.

Useful polymers that may be used as the template layer polymer include one or more polymers selected from the group consisting of styrene acrylonitrile copolymers; styrene(meth)acrylate copolymers; polymethylmethacrylate; styrene maleic anhydride copolymers; nucleated semi-crystalline polyesters; copolymers of polyethylenenaphthalate; polyimides; polyimide copolymers; polyetherimide; polystyrenes; syndiodactic polystyrene; polyphenylene oxides; and copolymers of acrylonitrile, butadiene, and styrene. Particularly useful polymers that may be used as the first extrudable polymer include styrene acrylonitrile copolymers known as TYRIL copolymers available from Dow Chemical; examples include TYRIL 880 and 125. Other particularly useful polymers that may be used as the template polymer include styrene maleic anhydride copolymer DYLARK 332 and styrene acrylate copolymer NAS 30, both from Nova Chemical. Also useful are polyethylene terephthalate blended with nucleating agents such as magnesium silicate, sodium acetate, or methylenebis(2,4-di-t-butylphenol) acid sodium phosphate.

Exemplary polymers useful as the top skin layer include CoPENs (copolymers of polyethylenenaphthalate), CoPVN (copolymers of polyvinylnaphthalene) and polyimides including polyetherimide. Suitable resin compositions include transparent materials that are dimensionally stable, durable, weatherable, and readily formable into the desired configuration. Examples of suitable materials include acrylics, which have an index of refraction of about 1.5, such as PLEXIGLAS brand resin manufactured by Rohm and Haas Company; polycarbonates, which have an index of refraction of about 1.59; reactive materials such as thermoset acrylates and epoxy acrylates; polyethylene based ionomers, such as those marketed under the brand name of SURLYN by E.I. Dupont de Nemours and Co., Inc.; (poly)ethylene-co-acrylic acid; polyesters; polyurethanes; and cellulose acetate butyrates. The template layer may be prepared by casting directly onto a support film, such as disclosed in U.S. Pat. No. 5,691,846 (Benson). Polymers for radiation cured structures include cross linked acrylates such as multifunctional acrylates or epoxies and acrylated urethanes blended with mono-and multifunctional monomers.

### Release Layer

The nanostructured template layer 324 must be removed from the underlying cured layer, such as OCL 312, to result in the nanostructured extraction surface 313. One method to reduce the adhesion of the OCL 312 layer (or nanostructured transfer layer, if included) to the nanostructured template layer 324 is to apply a release coating to the film. One method of applying a release coating to the surface of the template layer is with plasma deposition. An oligomer can be used to create a plasma cross-linked release coating. The oligomer may be in liquid or in solid form prior to coating. Typically the oligomer has a molecular weight greater than 1000. Also, the oligomer typically has a molecular weight less than 10,000 so that the oligomer is not too volatile. An oligomer with a molecular weight greater than 10,000 typically may be too non-volatile, causing droplets to form during coating. In one embodiment, the oligomer has a molecular weight greater than 3000 and less than 7000. In another embodiment, the oligomer has a molecular weight greater than 3500 and less than 5500. Typically, the oligomer has the properties of providing a low-friction surface coating. Suitable oligomers include silicone-containing hydrocarbons, reactive silicone containing trialkoxysilanes, aromatic and aliphatic hydrocarbons, fluorochemicals and combinations thereof. For examples, suitable resins include, but are not limited to, dimethylsilicone, hydrocarbon based polyether, fluorochemical polyether, ethylene teterafluoroethylene, and fluorosilicones. Fluorosilane surface chemistry, vacuum deposition, and surface fluorination may also be used to provide a release coating.

Plasma polymerized thin films constitute a separate class of material from conventional polymers. In plasma polymers, the polymerization is random, the degree of cross-linking is extremely high, and the resulting polymer film is very different from the corresponding “conventional” polymer film. Thus, plasma polymers are considered by those skilled in the art to be a uniquely different class of materials and are useful in the disclosed articles.

In addition, there are other ways to apply release coatings to the template layer known by those of skill in the art, including, but not limited to, blooming, coating, coextrusion, spray coating, electrocoating, or dip coating.

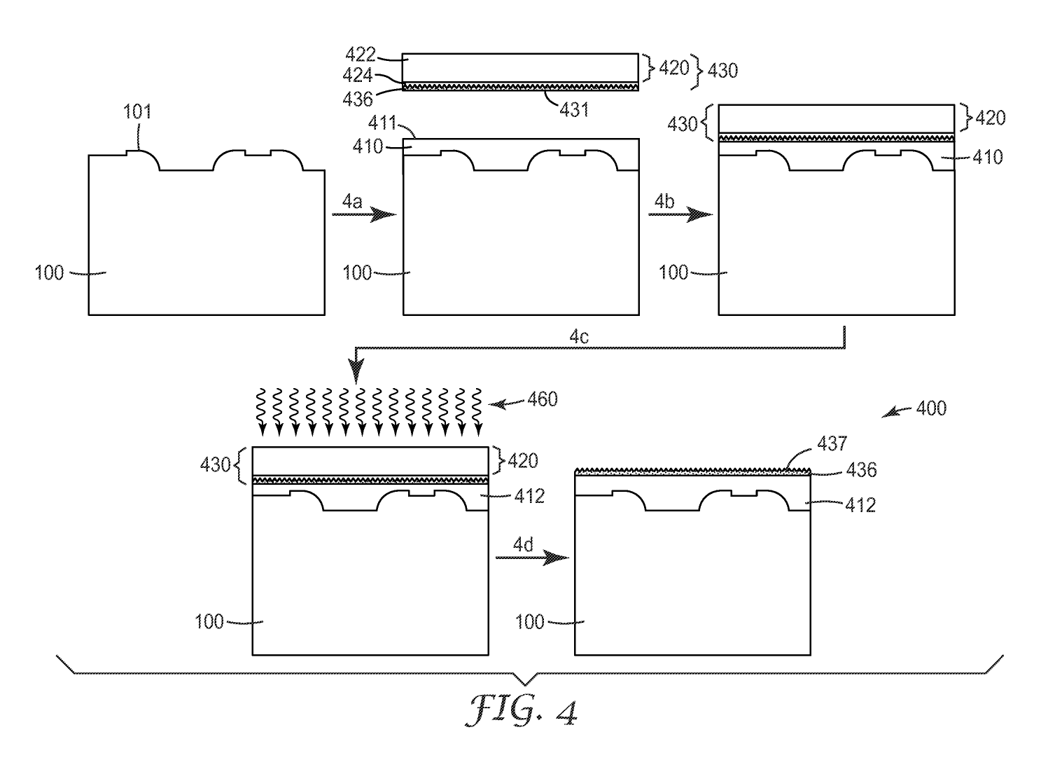

FIG. 4 shows a method for making a nanostructured AMOLED device 400, according to one aspect of the disclosure. The method for making a nanostructured AMOLED device 400 begins with an AMOLED 100 having a top surface 101, as described elsewhere with reference to FIG. 1. A pOCL 410 having a pOCL outer surface 411 is deposited on the top surface 101 (step 4a). A transfer film 430 including a nanostructured template film 420 having a nanostructured template layer 424 disposed on a support film 422 and a nanostructured transfer layer 436 (thereby forming an embedded nanostructure at the interface between the nanostructured template layer 424 and the nanostructured transfer layer 436) is applied to the pOCL 410 such that a planarized opposing nanostructured transfer layer surface 431 contacts the pOCL outer surface 411 (step 4b). In one particular embodiment, transfer film 430 can be provided on a release liner (also referred to as a premask or protective liner, not shown, as described elsewhere) that is removed prior to lamination, in order to protect the planarized opposing nanostructured transfer layer surface 431 during handling. Actinic radiation 460 is applied through the transfer film 430, curing the pOCL 410 to become an OCL 412 bonded to the nanostructured transfer layer 436 (step 4c). The nanostructured template film 420 can then be removed from the nanostructured transfer layer 436, exposing the nanostructured extraction surface 437 and resulting in the nanostructured AMOLED device 400 (step 4d). In this case, nanostructured transfer layer 436 can be the same or different material as the pOCL 410.

Materials that are suitable for the pOCL 410 are also suitable for the nanostructured transfer layer 436. The converse is not necessarily true. Some materials that exhibit high film stress may be appropriate for the relatively thin nanostructured transfer layer 436, but unsuitable for the thicker OCL 412 layer (e.g. some silsesquioxanes and “spin on glasses”). In addition, since transfer film 430 is fabricated separately from the AMOLED 100, the nanostructured transfer layer 436 may be prepared using chemical, thermal, or photochemical methods that are incompatible with the AMOLED 100. For example, nanostructured transfer layer 436 may be heated to high temperatures, coated from solvents, and exposed to intense irradiation, each of which is a technique that may be incompatible with an AMOLED 100, and therefore not available for use with suitable pOCL 410 materials.

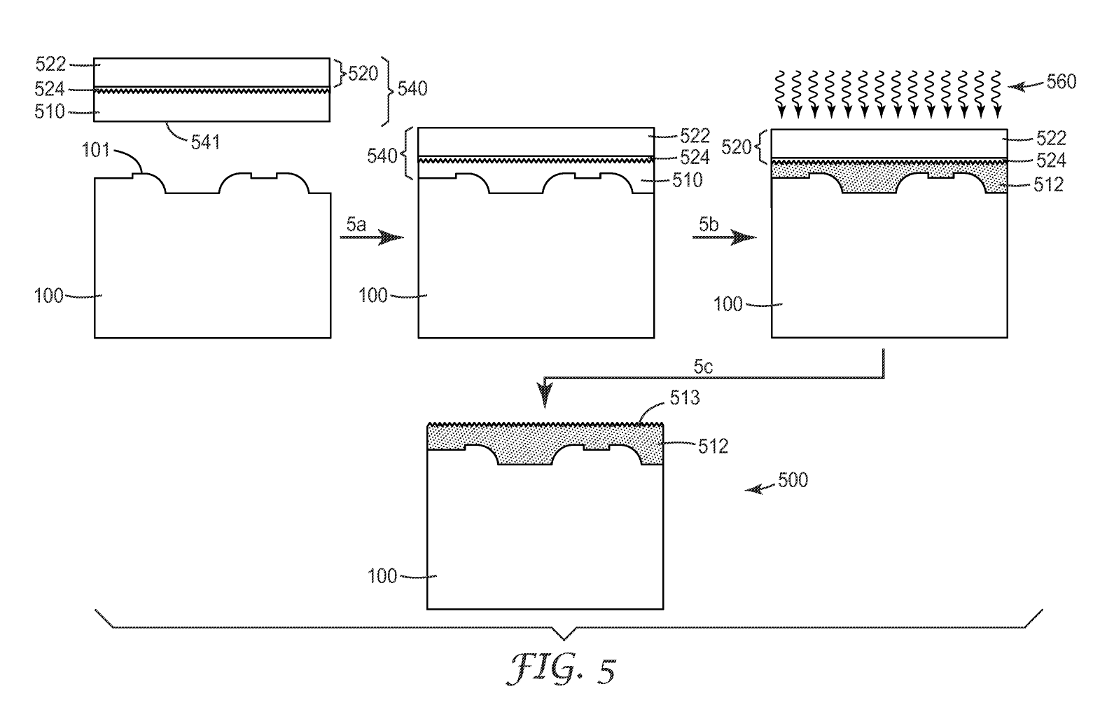

FIG. 5 shows a method for making a nanostructured AMOLED device 500, according to one aspect of the disclosure. The method for making a nanostructured AMOLED device 500 begins with an AMOLED 100 having a top surface 101, as described elsewhere with reference to FIG. 1. A transfer film 540 including a nanostructured template film 520 having a nanostructured template layer 524 disposed on a support film 522, and a pOCL 510 disposed on the nanostructured template layer 524 such that the transfer film 540 includes a pOCL planar surface 541 opposite the nanostructured template layer 524. The pOCL planar surface 541 of the transfer film 540 is laminated to the top surface 101 of AMOLED 100 (step 5a). In one particular embodiment, transfer film 540 can be provided on a release liner (not shown, as described elsewhere) that is removed prior to lamination, in order to protect the pOCL planar surface 541 during handling. Actinic radiation 560 is applied through the transfer film 530, curing the pOCL 510 to become an OCL 512 bonded to the top surface 101 of the AMOLED 100 (step 5b). The nanostructured template film 520 can then be removed from the OCL 512, exposing the nanostructured extraction surface 513 and resulting in the nanostructured AMOLED device 500 (step 5c).

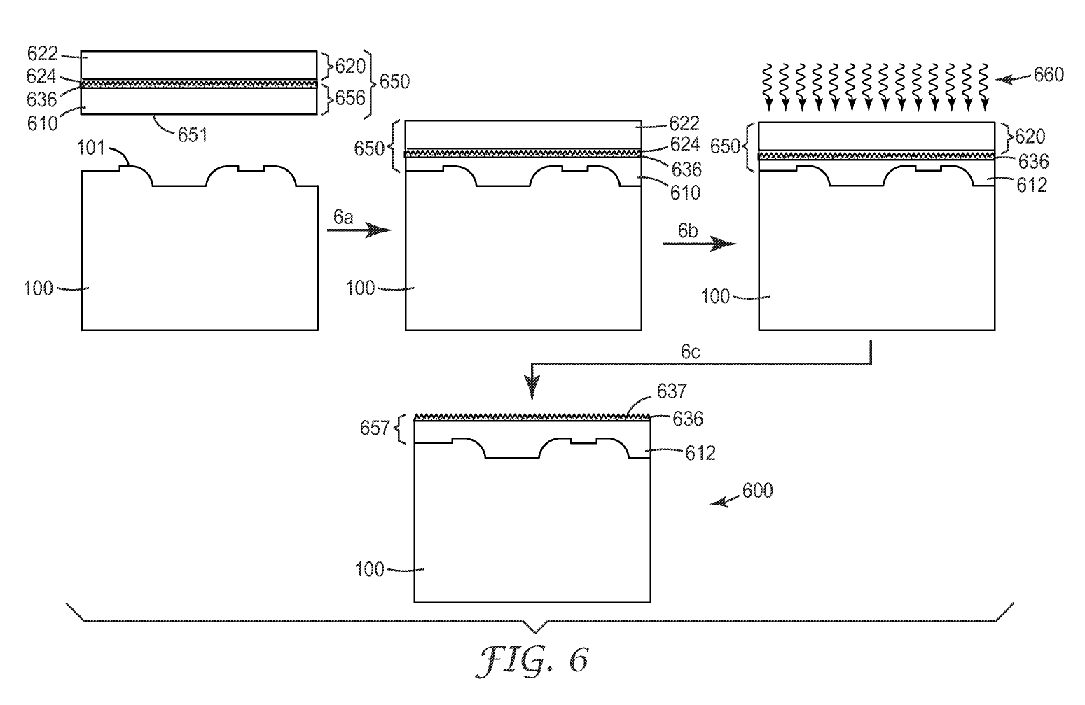

FIG. 6 shows a method for making a nanostructured AMOLED device 600, according to one aspect of the disclosure. The method for making a nanostructured AMOLED device 600 begins with an AMOLED 100 having a top surface 101, as described elsewhere with reference to FIG. 1. A transfer film 650 including a nanostructured template film 620 having a nanostructured template layer 624 disposed on a support film 622, and a multicomponent transfer layer 656 is disposed on the nanostructured template layer 624. The multicomponent transfer layer 656 has a nanostructured transfer layer 636 in contact with the nanostructured template layer 624, and a pOCL 610 disposed on the nanostructured transfer layer 636 such that the transfer film 650 has a pOCL planar surface 651 opposite the nanostructured transfer layer 636. The pOCL planar surface 651 of the transfer film 650 is laminated to the top surface 101 of AMOLED 100 (step 6a). In one particular embodiment, transfer film 650 can be provided on a release liner (not shown, as described elsewhere) that is removed prior to lamination, in order to protect the pOCL planar surface 651 during handling. Actinic radiation 660 is applied through the transfer film 650, curing the pOCL 610 to become an OCL 612 bonded to the top surface 101 of the AMOLED 100 (step 6b). The nanostructured template film 620 can then be removed from the cured multicomponent transfer layer 657, exposing the nanostructured extraction surface 637 of the nanostructured transfer layer 636 bonded to the OCL 612, resulting in the nanostructured AMOLED device 600 (step 6c).

Materials that are suitable for the pOCL 610 are also suitable for the nanostructured transfer layer 636. The converse is not necessarily true. Some materials that exhibit high film stress may be appropriate for the relatively thin nanostructured transfer layer 636, but unsuitable for the thicker OCL 612 layer (e.g. some silsesquioxanes and “spin on glasses”). In addition, the nanostructured transfer layer 636 may be prepared using chemical, thermal, or photochemical methods that are incompatible with the pOCL 610 of the multicomponent transfer layer 656. For example, nanostructured transfer layer 636 may be heated to high temperatures, coated from solvents, and exposed to intense irradiation, each of which is a technique that may be incompatible with pOCL 610 materials.

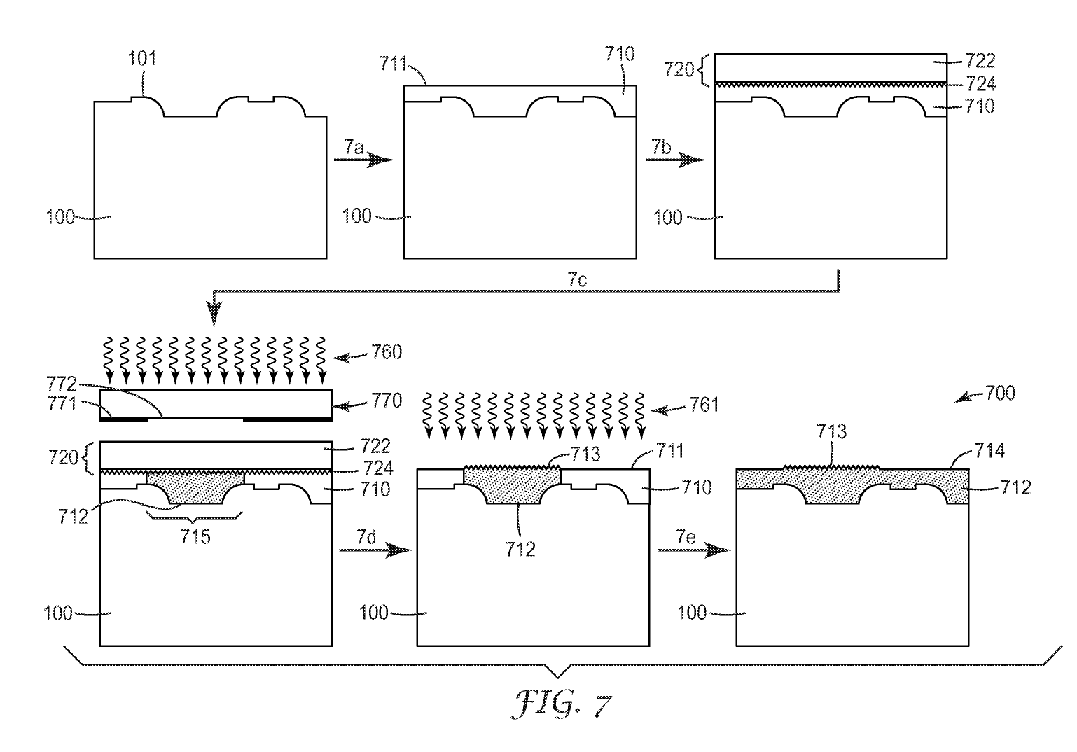

FIG. 7 shows a method for making a nanostructured AMOLED device 700, according to one aspect of the disclosure. The method for making a nanostructured AMOLED device 700 begins with an AMOLED 100 having a top surface 101, as described elsewhere with reference to FIG. 1. In this method, nanostructures can be applied only to regions of the AMOLED 100 where improved extraction is desired. A pOCL 710 having a pOCL planar surface 711 is deposited on the top surface 101 (step 7a). A nanostructured template film 720 having a nanostructured template layer 724 disposed on a support film 722 is applied to the pOCL 710 such that a nanostructured template layer surface 721 contacts the pOCL, and the pOCL 710 flows to fill the nanostructured template layer surface 721 (step 7b). In one particular embodiment, nanostructured template film 720 can be provided on a release liner (not shown, as described elsewhere) that is removed prior to lamination, in order to protect the nanostructured template layer 724 during handling. Actinic radiation 760 is applied to the nanostructured template film 720 through a mask 770 having open regions 772 where the actinic radiation 760 can pass through, and blocked regions 771 which block the passage of the actinic radiation. The pOCL 710 is cured in cured regions 715 adjacent the open regions 772 to become an OCL 712, whereas adjacent the blocked regions 771, the pOCL 710 remains uncured (step 7c). The nanostructured template film 720 can then be removed from the OCL 712, exposing the nanostructured extraction surface 713 adjacent the OCL 712, and the remaining pOCL 710 can be subjected to reflow conditions (e.g., increased temperature) such that a pOCL planar surface 711 results (step 7d). Actinic radiation 761 is again applied to the OCL 712 having a nanostructured extraction surface 713 and the pOCL 710 having a pOCL planar surface 711, to result in the OCL 712 having nanostructured extraction surface 713 and OCL planar surface 714, and finally resulting in the nanostructured AMOLED device 700 (step 7e).

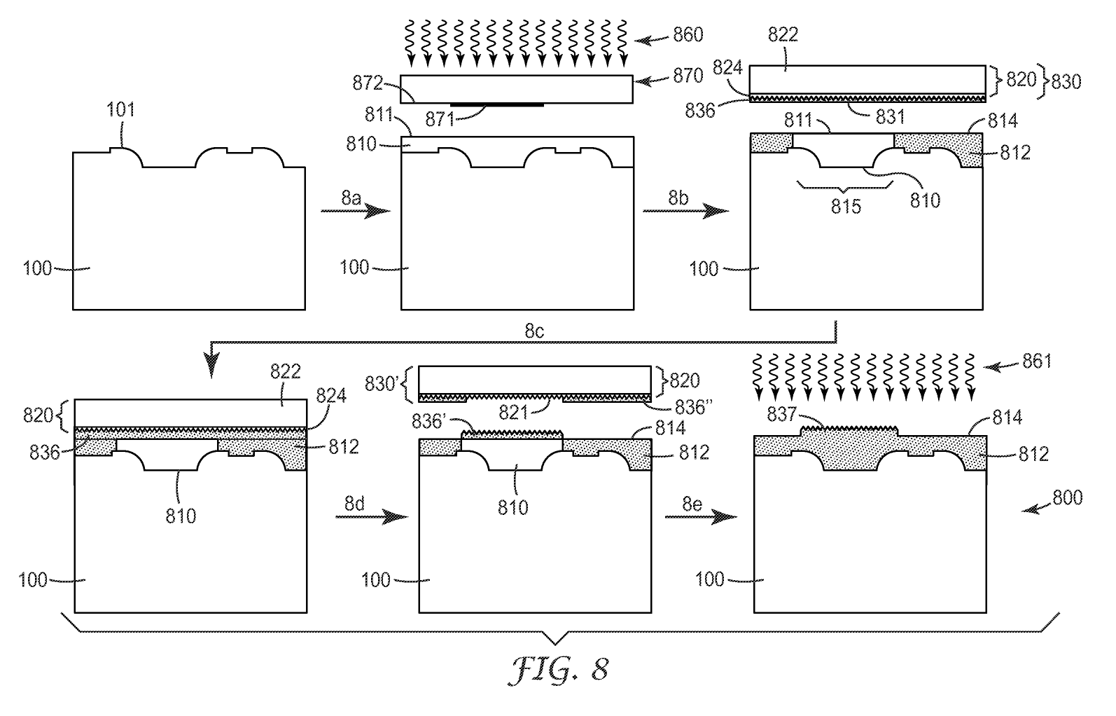

FIG. 8 shows a method for making a nanostructured AMOLED device 800, according to one aspect of the disclosure. The method for making a nanostructured AMOLED device 800 begins with an AMOLED 100 having a top surface 101, as described elsewhere with reference to FIG. 1. In this method, nanostructures can be applied selectively, and only to regions of the AMOLED 100 where improved extraction is desired. A pOCL 810 having a pOCL planar surface 811 is deposited on the top surface 101 (step 8a). Actinic radiation 860 is applied to the pOCL 810 through a mask 870 having open regions 872 where the actinic radiation 860 can pass through, and blocked regions 871 which block the passage of the actinic radiation 860. The pOCL 810 remains uncured in uncured regions 815 adjacent the blocked regions 871 and remains tacky, whereas adjacent the open regions 872 the pOCL 810 is cured to become an OCL 812 having OCL planar surface 814 that is no longer tacky (step 8b). A transfer film 830 including a nanostructured template film 820 having a nanostructured template layer 824 disposed on a support film 822 and a nanostructured transfer layer 836 is laminated to the pOCL 810 and OCL 812 such that a planarized opposing nanostructured transfer layer surface 831 contacts the pOCL planar surface 811 and OCL planar surface 814 (step 8c). In one particular embodiment, transfer film 830 can be provided on a release liner (not shown, as described elsewhere) that is removed prior to lamination, in order to protect the planarized opposing nanostructured transfer layer surface 831 during handling. The modified transfer film 830′ is removed, thereby depositing transferred nanostructured transfer layer 836′ adhered to pOCL planar surface 811 only in uncured regions 815 (step 8d). The areas of untransferred nanostructured transfer layer 836″ that are not adhered to the pOCL planar surface 811 remain attached to the modified transfer film 830′ as it is removed. Actinic radiation 861 is again applied to the pOCL 810 having transferred nanostructured transfer layer 836′ and the OCL 812 having a OCL planar surface 814 to result in the OCL 812 having nanostructured extraction surface 837 and OCL planar surface 814, and resulting in the nanostructured AMOLED device 800 (step 8e). In this case, nanostructured transfer layer 836 can be the same or different material as the pOCL 810 or OCL 812.

Materials that are suitable for the pOCL 810 are also suitable for the nanostructured transfer layer 836. The converse is not necessarily true. Some materials that exhibit high film stress may be appropriate for the relatively thin nanostructured transfer layer 836 but unsuitable for the thicker OCL 812 layer (e.g. some silsesquioxanes and “spin on glasses”). In addition, since transfer film 830 is fabricated separately from the AMOLED 100, the nanostructured transfer layer 836 may be prepared using chemical, thermal, or photochemical methods that are incompatible with the AMOLED 100. For example, nanostructured transfer layer 836 may be heated to high temperatures, coated from solvents, and exposed to intense irradiation, each of which is a technique that may be incompatible with an AMOLED 100, and therefore not available for use with suitable pOCL 810 materials.

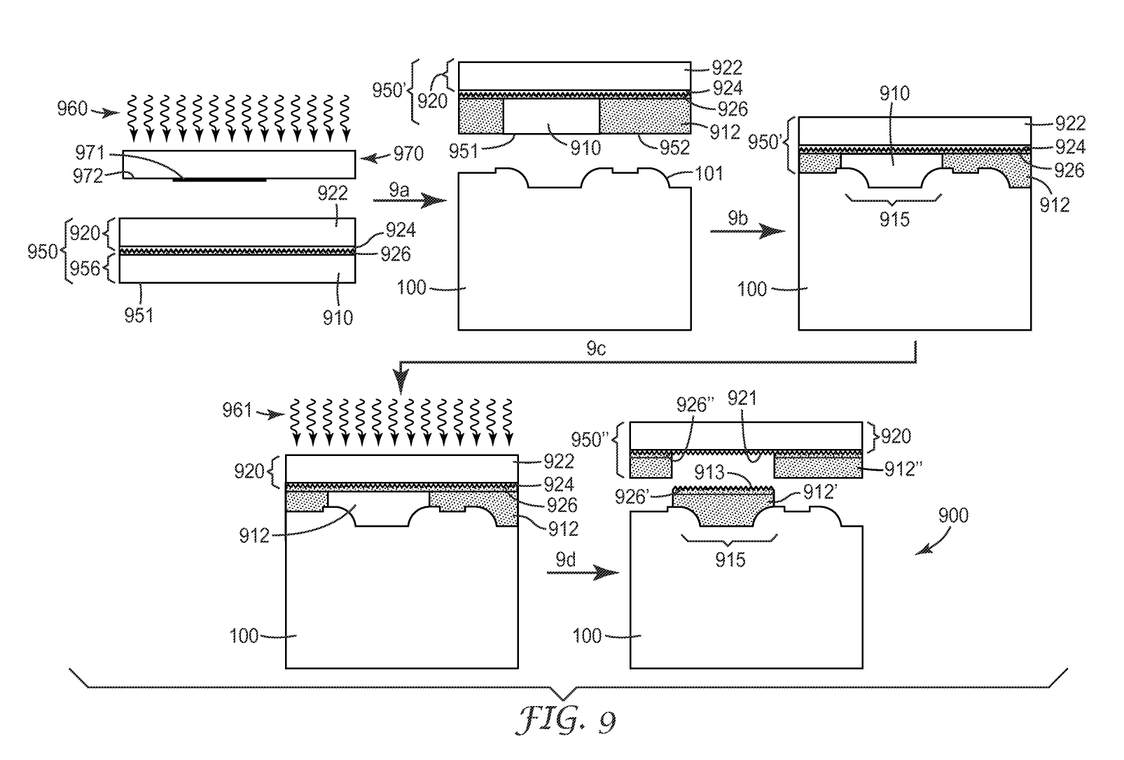

FIG. 9 shows a method for making a nanostructured AMOLED device 900, according to one aspect of the disclosure. In this method, nanostructures can be applied only to regions of an AMOLED 100 where improved extraction is desired. The method for making a nanostructured AMOLED device 900 begins with a transfer film 950 including a nanostructured template film 920 having a nanostructured template layer 924 disposed on a support film 922, and a multicomponent transfer layer 956 disposed on the nanostructured template layer 924. The multicomponent transfer layer 956 has a nanostructured transfer layer 926 in contact with the nanostructured template layer 924, and a pOCL 910 disposed on the nanostructured transfer layer 926, the pOCL 910 including a pOCL planar surface 951. In one particular embodiment, transfer film 950 can be provided on a release liner (not shown, as described elsewhere) that is removed prior to lamination, in order to protect the pOCL planar surface 951 during handling. Actinic radiation 960 is applied to the pOCL 910 through a mask 970 having open regions 972 where the actinic radiation 960 can pass through, and blocked regions 971 which block the passage of the actinic radiation 960, resulting in a modified transfer film 950′. The modified transfer film 950′ includes pOCL 910 that remains uncured in areas adjacent the blocked regions 971 and a pOCL planar surface 951 that remains tacky, whereas adjacent the open regions 972 the pOCL 910 is cured to become an OCL 912 having an OCL planar surface 952 that is no longer tacky, and is also adhered to the nanostructured transfer layer 926. The modified transfer film 950′ is aligned to the AMOLED 100 having a top surface 101, as described elsewhere with reference to FIG. 1, such that the uncured pOCL 910 is aligned with the areas on AMOLED 100 where extraction features are desired (step 9a). The modified transfer film 950′ is then laminated to the AMOLED 100, such that the tacky uncured pOCL 910 contacts top surface 101 in extraction region 915 (step 9b). Actinic radiation 961 is applied through the modified transfer film 950′, curing and bonding the pOCL 910 in extraction region 915 to become a cured transferred OCL 912′ that is adhered to the top surface 101 of the AMOLED 100 and also adhered to the nanostructured transfer layer 926 (step 9c). The reduced modified transfer film 950″ can then be removed from the cured transferred OCL 912′ and transferred nanostructured transfer layer 926′, exposing the nanostructured extraction surface 913, the cured transferred OCL 912′ being bonded to the AMOLED 100 in extraction region 915, resulting in the nanostructured AMOLED device 900 (step 9d). The areas of the untransferred nanostructured transfer layer 912″ and untransferred nanostructured transfer layer 926″ that are not adhered to the top surface 101 remain attached to the reduced modified transfer film 950″ as it is removed. In this case, nanostructured transfer layer 926 can be the same or different material as the pOCL 910 or OCL 912.

Materials that are suitable for the pOCL 910 are also suitable for the nanostructured transfer layer 926. The converse is not necessarily true. Some materials that exhibit high film stress may be appropriate for the relatively thin nanostructured transfer layer 926, but unsuitable for the thicker OCL 912 layer (e.g. some silsesquioxanes and “spin on glasses”). In addition, the nanostructured transfer layer 926 may be prepared using chemical, thermal, or photochemical methods that are incompatible with the pOCL 910 of the multicomponent transfer layer 956. For example, nanostructured transfer layer 926 may be heated to high temperatures, coated from solvents, and exposed to intense irradiation, each of which is a technique that may be incompatible with pOCL 910 materials.

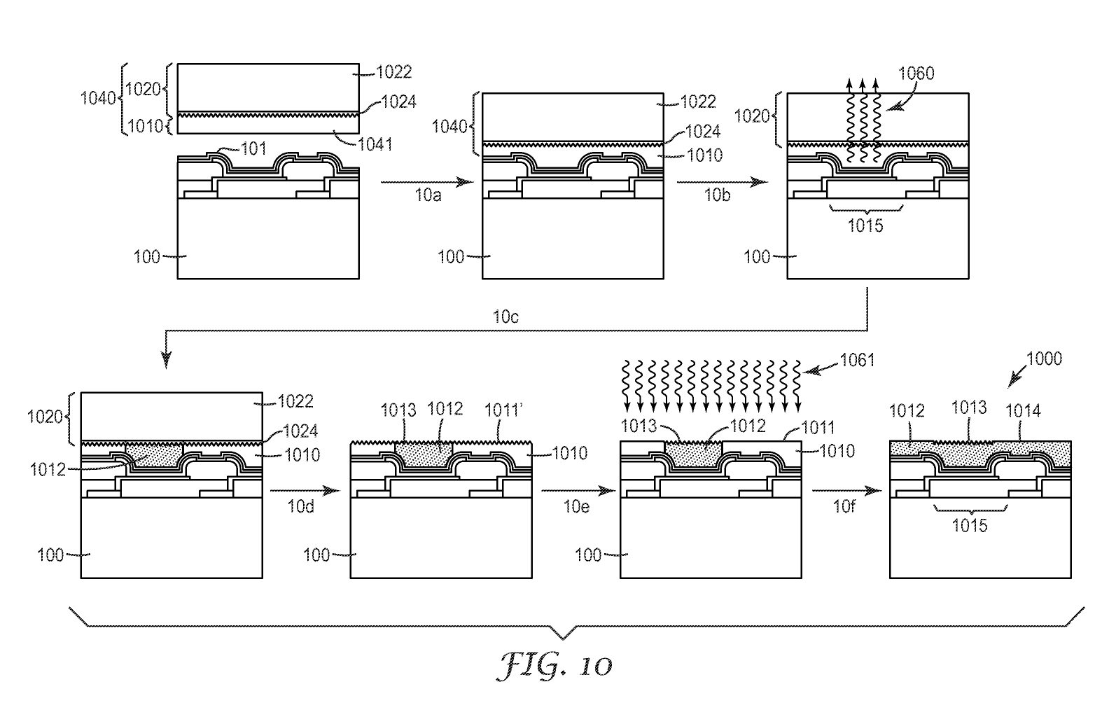

FIG. 10 shows a method for making a nanostructured AMOLED device 1000, according to one aspect of the disclosure. The method for making a nanostructured AMOLED device 1000 begins with an AMOLED 100 having a top surface 101, as described elsewhere with reference to FIG. 1. A transfer film 1040 including a nanostructured template film 1020 having a nanostructured template layer 1024 disposed on a support film 1022, and a pOCL 1010 disposed on the nanostructured template layer 1024 such that the transfer film 1040 includes a pOCL planar surface 1041 opposite the nanostructured template layer 1024. In one particular embodiment, transfer film 1040 can be provided on a release liner (not shown, as described elsewhere) that is removed prior to lamination, in order to protect the pOCL planar surface 1041 during handling. The pOCL planar surface 1041 of the transfer film 1040 is laminated to the top surface 101 of AMOLED 100 (step 10a). Actinic radiation 1060 is applied to the transfer film 530 by emission from an OLED pixel 1015, curing the pOCL 1010 (step 10b) to become an OCL 1012 bonded to the top surface 101 of the AMOLED 100, adjacent uncured pOCL 1010 regions (step 10c). The nanostructured template film 1020 can then be removed from the OCL 1012 and pOCL 1010, exposing the nanostructured extraction surface 513 and pOCL 1010 having nanostructured pOCL surface 1011′ (step 10d). The remaining uncured pOCL 1010 can be subjected to reflow conditions (e.g., increased temperature) such that a pOCL planar surface 1011 results (step 10e). Actinic radiation 1061 is again applied to the OCL 1012 having a nanostructured extraction surface 1013 and the pOCL 1010 having a pOCL planar surface 1011 to result in the OCL 1012 having nanostructured extraction surface 1013 proximate OLED pixel 1015, and OCL planar surface 1014 elsewhere, resulting in the nanostructured AMOLED device 1000 (step 10f).

### Adhesion Promoting Layer Materials

An adhesion promoting layer can be implemented with any material enhancing adhesion of the transfer film to the receptor substrate without substantially adversely affecting the performance of the transfer film. The exemplary materials for the transfer layer and OCL layers can also be used for the adhesion promoting layer, which preferably has a high index of refraction. Useful adhesion promoting materials useful in the disclosed articles and methods include photoresists (positive and negative), self-assembled monolayers, adhesives, silane coupling agents, and macromolecules. In some embodiments, silsesquioxanes can function as adhesion promoting layers. For example, polyvinyl silsesquioxane polymers can be used as an adhesion promoting layer. Other exemplary materials may include benzocyclobutanes, polyimides, polyamides, silicones, polysiloxanes, silicone hybrid polymers, (meth)acrylates, and other silanes or macromolecules functionalized with a wide variety of reactive groups such as epoxide, episulfide, vinyl, hydroxyl, allyloxy, (meth)acrylate, isocyanate, cyanoester, acetoxy, (meth)acrylamide, thiol, silanol, carboxylic acid, amino, vinyl ether, phenolic, aldehyde, alkyl halide, cinnamate, azide, aziridine, alkene, carbamates, imide, amide, alkyne, and any derivatives or combinations of these groups.

### Release Liners

The transfer layer, OCL layer, pOCL layer, or other transferrable layer, can, optionally, be covered with a temporary release liner. The release liner can protect the patterned structured layer during handling and can be easily removed, when desired, for transfer of the structured layer or part of the structured layer to a receptor substrate. Exemplary liners useful for the disclosed patterned structured tape are disclosed in PCT Pat. Appl. Publ. No. WO 2012/082536 (Baran et al.).

The liner may be flexible or rigid. Preferably, it is flexible. A suitable liner (preferably, a flexible liner) is typically at least 0.5 mil thick, and typically no more than 20 mils thick. The liner may be a backing with a release coating disposed on its first surface. Optionally, a release coating can be disposed on its second surface. If this backing is used in a transfer article that is in the form of a roll, the second release coating has a lower release value than the first release coating. Suitable materials that can function as a rigid liner include metals, metal alloys, metal-matrix composites, metalized plastics, inorganic glasses and vitrified organic resins, formed ceramics, and polymer matrix reinforced composites.

Exemplary liner materials include paper and polymeric materials. For example, flexible backings include densified Kraft paper (such as those commercially available from Loparex North America, Willowbrook, Ill.), poly-coated paper such as polyethylene coated Kraft paper, and polymeric film. Suitable polymeric films include polyester, polycarbonate, polypropylene, polyethylene, cellulose, polyamide, polyimide, polysilicone, polytetrafluoroethylene, polyethylenephthalate, polyvinylchloride, polycarbonate, or combinations thereof. Nonwoven or woven liners may also be useful. Embodiments with a nonwoven or woven liner could incorporate a release coating. CLEARSIL T50 Release liner; silicone coated 2 mil polyester film liner, available from Solutia/CP Films, Martinsville, Va., and LOPAREX 5100 Release Liner, fluorosilicone-coated 2 mil polyester film liner available from Loparex, Hammond, Wis., are examples of useful release liners.

The release coating of the liner may be a fluorine-containing material, a silicon-containing material, a fluoropolymer, a silicone polymer, or a poly(meth)acrylate ester derived from a monomer comprising an alkyl(meth)acrylate having an alkyl group with 12 to 30 carbon atoms. In one embodiment, the alkyl group can be branched. Illustrative examples of useful fluoropolymers and silicone polymers can be found in U.S. Pat. Nos. 4,472,480 (Olson), 4,567,073 and 4,614,667 (both Larson et al.). Illustrative examples of a useful poly(meth)acrylate ester can be found in U.S. Pat. Appl. Publ. No. 2005/118352 (Suwa). The removal of the liner shouldn't negatively alter the surface topology of the transfer layer.

### Other Additives

Other suitable additives to include in the transfer, OCL, pOCL, and adhesion promotion layer are antioxidants, stabilizers, antiozonants and/or inhibitors to prevent premature curing during the process of storage, shipping and handling of the film. Preventing premature curing can maintain the tack required for lamination transfer in all previously mentioned embodiments. Antioxidants can prevent the formation of free radical species, which may lead to electron transfers and chain reactions such as polymerization. Antioxidants can be used to decompose such radicals. Suitable antioxidants may include, for example, antioxidants under the IRGANOX tradename. The molecular structures for antioxidants are typically hindered phenolic structures, such as 2,6-di-tert-butylphenol, 2,6-di-tert-butyl-4-methylphenol, or structures based on aromatic amines. Secondary antioxidants are also used to decompose hydroperoxide radicals, such as phosphites or phosphonites, organic sulphur containing compounds and dithiophosphonates. Typical polymerization inhibitors include quinone structures such hydroquinone, 2,5 di-tert-butyl-hydroquinone, monomethyl ether hydroquinone or catechol derivatives such as 4-tert butyl catechol. Any antioxidants, stabilizers, antiozonants and inhibitors used must be soluble in the transfer, OCL, and adhesion promotion layer.

### EXAMPLES

### Example 1

### Transfer of a Structure to a Glass Substrate

A pixel defining layer (PDL) was applied to a glass substrate by spin coating a photoresist (TELR-P003 PM, available from Toyko Ohka Kogyo America Inc., Milpitas, Calif.) onto the substrate at a thickness of about 500 nm, and patterning the coated layer to a series of 4 mm×4 mm square openings, by UV curing through a PDL Photomask (available from Infinite Graphics Inc., Minneapolis, Minn.).

A film tool having a structure with 90 degree prisms having a width of 600 nm each, was created using UV radiation replication process on a PET substrate. The substrate used was a primed 0.002 inch (0.051 mm) thick PET. The replicating resin was a 75/25 blend of SR 399 and SR238 (both available from Sartomer USA, Exton, Pa.) with a photoinitator package comprising 1% Darocur 1173 (Available from Ciba, Tarrytown, N.Y.), 1.9% triethanolamine (available from Sigma-Aldrich, St. Louis, Mo.), and 0.5% OMAN071 (available from Gelest, Inc. Morrisville, Pa.). Replication of the resin was conducted at 20 ft/min (6.1 m/min) with the replication tool temperature at 137 deg F (58 deg C). Radiation from a Fusion “D” lamp operating at 600 W/in was transmitted through the film to cure the resin while in contact with the tool. The composite film was removed from the tool and the patterned side of the film was post UV cured using a Fusion “D” lamp operating at 360 W/in while in contact with a chill roll heated to 100 deg F (37.8 deg C).

The replicated template film was primed in a plasma chamber using argon gas at a flow rate of 250 standard cc/min (SCCM), a pressure of 25 mTorr and RF power of 1000 Watts for 30 seconds. Subsequently, a release coated tool surface was prepared by subjecting the samples to a tetramethylsilane (TMS) plasma at a TMS flow rate of 150 SCCM but no added oxygen, which corresponded to an atomic ratio of oxygen to silicon of about 0. The pressure in the plasma chamber was 25 mTorr, and the RF power of 1000 Watts was used for 10 seconds.

A pOCL coating solution (high refractive index Acryl Resin #6205; n>1.7, available from NTT Advanced Technology, Tokyo, JP) was then hand coated onto the release coated tool surface with a notch bar coater, creating a structured transfer tape. Approximately 50 milliliters of the coating solution was applied to the release coated tool and pulled through a notch bar coater set with a gap of 0.008 inches. The coating was dried in the dark at ambient temperature and humidity for 1 hour.

The coated tool was then laminated facedown onto the pixel defining layer containing glass substrate in a heated nip, and the resulting laminate was UV cured using a Fusion “H” bulb. The tool was removed, resulting in a structured OCL layer on the pixel defining layer.

### Example 2

A structured transfer tape is made as in Example 1. An OLED is constructed with a pixel defining layer on the surface. The structured transfer tape is laminated to the top surface of the OLED construction. The laminate is cured with actinic radiation and the release coated tool is removed from the laminate resulting in an OLED having a nanostructured exterior surface.

Following are a list of embodiments of the present disclosure.

Item 1 is an image display, comprising: at least one organic light emitting diode (OLED) having a top surface; a high index optical coupling layer in contact with the top surface, the high index optical coupling layer having a nanostructured exterior surface.

Item 2 is the image display of item 1, wherein the nanostructured exterior surface is integral with the high index optical coupling layer.

Item 3 is the image display of item 1 or item 2, wherein the nanostructured exterior surface comprises a nanostructured transfer layer disposed on the high index optical coupling layer.

Item 4 is the image display of item 1 to item 3, wherein the nanostructured exterior surface includes selected nanostructured regions and adjacent planar regions.

Item 5 is the image display of item 4, wherein at least one of the selected nanostructured regions is disposed over emissive regions of the OLED.

Item 6 is the image display of item 1 to item 5, wherein the optical coupling layer comprises a hybrid material.

Item 7 is the image display of item 6, wherein the hybrid material comprises a nanoparticle-filled acrylate or a nanoparticle-filled silsesquioxane.

Item 8 is a method, comprising: coating an optical coupling layer (OCL) precursor on a top surface of an OLED array, forming a planarized OCL precursor surface; laminating a template film having a nanostructured surface onto the OCL precursor surface such that the OCL precursor at least partially fills the nanostructured surface; polymerizing the OCL precursor to form a nanostructured OCL; and removing the template film.

Item 9 is the method of item 8, wherein polymerizing comprises actinic radiation curing, thermal curing, or a combination thereof.

Item 10 is the method of item 9, wherein the actinic radiation comprises ultraviolet radiation or electron beam radiation.

Item 11 is the method of item 8 to item 10, wherein the nanostructured surface of the template film comprises a release coating.

Item 12 is the method of item 8 to item 10, wherein the top surface of the OLED display comprises an adhesion promoting primer.

Item 13 is a method, comprising: coating an optical coupling layer (OCL) precursor on a top surface of an OLED array, forming a planarized OCL precursor surface; laminating a template film onto the OCL precursor surface such that a planar outer surface of the transfer layer of the template film contacts the OCL precursor surface, wherein the transfer layer includes an embedded nanostructured surface; polymerizing the OCL precursor to form the OCL and bond the planar outer surface of the transfer layer to the OCL; and removing the template film from the transfer layer.

Item 14 is the method of item 13, wherein polymerizing comprises actinic radiation curing, thermal curing, or a combination thereof.

Item 15 is the method of item 14, wherein the actinic radiation comprises ultraviolet radiation or electron beam radiation.

Item 16 is the method of item 13 to item 15, wherein the embedded nanostructured surface of the template film comprises a release coating.

Item 17 is the method of item 13 to item 16, wherein at least one of the top surface of the OLED display, the planarized OCL precursor, and the planar outer surface, comprises an adhesion promoting primer.

Item 18 is a method, comprising: coating an optical coupling layer (OCL) precursor on a nanostructured surface of a template film; laminating the template film onto a major surface of an OLED array such that the OCL precursor contacts the major surface; polymerizing the OCL precursor to form the OCL and bond the OCL to the major surface of the OLED array; and removing the template film.

Item 19 is the method of item 18, wherein polymerizing comprises actinic radiation curing, thermal curing, or a combination thereof.

Item 20 is the method of item 19, wherein the actinic radiation comprises ultraviolet radiation or electron beam radiation.

Item 21 is the method of item 18 to item 20, wherein the nanostructured surface comprises a release coating.

Item 22 is the method of item 18 to item 21, wherein the top surface of the OLED display comprises an adhesion promoting primer.

Item 23 is a method, comprising: forming a nanostructured layer on a nanostructured surface of a template film such that the nanostructured layer has a planar outer surface and an embedded nanostructured surface; coating an optical coupling layer (OCL) precursor on the planar outer surface to form a transfer film; laminating the transfer film onto a major surface of an OLED array such that the OCL precursor contacts the major surface; polymerizing the OCL precursor to form the OCL and bond the OCL to the major surface of the OLED array; and removing the template film from the nanostructured layer.

Item 24 is the method of item 23, wherein polymerizing comprises actinic radiation curing, thermal curing, or a combination thereof.

Item 25 is the method of item 24, wherein the actinic radiation comprises ultraviolet radiation or electron beam radiation.

Item 26 is the method of item 23 to item 25, wherein the embedded nanostructured surface comprises a release coating.

Item 27 is the method of item 23 to item 26, wherein the top surface of the OLED display comprises an adhesion promoting primer.

Item 28 is a method, comprising: coating an optical coupling layer (OCL) precursor on a top surface of an OLED array, forming a planarized OCL precursor surface; laminating a template film having a nanostructured surface onto the planarized OCL precursor surface such that the OCL precursor at least partially fills the nanostructured surface; polymerizing the OCL precursor in selected regions to form a patterned nanostructured OCL having unpolymerized regions; removing the template film; and polymerizing the unpolymerized regions.

Item 29 is the method of item 28, wherein polymerizing comprises actinic radiation curing, thermal curing, or a combination thereof.

Item 30 is the method of item 29, wherein the actinic radiation comprises ultraviolet radiation or electron beam radiation.

Item 31 is the method of item 28 to item 30, wherein the nanostructured surface comprises a release coating.

Item 32 is the method of item 28 to item 31, wherein the top surface of the OLED display comprises an adhesion promoting primer.

Item 33 is the method of item 28 to item 32, further comprising reflowing the unpolymerized regions after removing the transfer film and before polymerizing the unpolymerized regions.

Item 34 is the method of item 33, wherein reflowing comprises planarizing the unpolymerized regions by heating.

Item 35 is the method of item 28 to item 34, wherein polymerizing the OCL precursor in selected regions comprises self-registered photoexposure from at least one OLED pixel emission.

Item 36 is a method, comprising: coating an optical coupling layer (OCL) precursor on a top surface of an OLED array, forming a planarized OCL precursor surface; masking selected regions of the OCL precursor to prevent polymerization; polymerizing the OCL precursor to form a patterned OCL having unpolymerized regions; laminating a transfer film onto the patterned OCL such that a transfer layer of the transfer film contacts a major surface of the patterned OCL, wherein the transfer layer includes a planar outer surface and an embedded nanostructured surface; removing the transfer film from the patterned OCL, leaving the transfer layer in the selected regions; and polymerizing the unpolymerized regions of the patterned OCL to bond the planar outer transfer layer to the selected regions of the OCL.

Item 37 is the method of item 36, wherein polymerizing comprises actinic radiation curing, thermal curing, or a combination thereof.

Item 38 is the method of item 37, wherein the actinic radiation comprises ultraviolet radiation or electron beam radiation.

Item 39 is the method of item 36 to item 38, wherein the embedded nanostructured surface comprises a release coating.

Item 40 is the method of item 36 to item 39, wherein the top surface of the OLED display comprises an adhesion promoting primer.

Item 41 is a method, comprising: forming a transfer layer on a nanostructured surface of a transfer film such that the transfer layer has a planar outer surface and an embedded nanostructured surface; coating an optical coupling layer (OCL) precursor on the planar outer surface; masking selected regions of the OCL precursor to prevent polymerization; polymerizing the OCL precursor to form a patterned OCL having unpolymerized transferable OCL regions; laminating the transfer film onto a major surface of an OLED array such that the unpolymerized transferable OCL regions contact the major surface; polymerizing the unpolymerized transferable OCL regions to form a bonded patterned nanostructured OCL on the major surface of the OLED array; and removing the transfer film from the major surface of the OLED array, leaving the bonded patterned nanostructured OCL on the major surface of the OLED array.

Item 42 is the method of item 41, wherein polymerizing comprises actinic radiation curing, thermal curing, or a combination thereof.

Item 43 is the method of item 42, wherein the actinic radiation comprises ultraviolet radiation or electron beam radiation.

Item 44 is the method of item 41 to item 43, wherein the embedded nanostructured surface comprises a release coating.

Item 45 is the method of item 41 to item 44, wherein the top surface of the OLED display comprises an adhesion promoting primer.

Unless otherwise indicated, all numbers expressing feature sizes, amounts, and physical properties used in the specification and claims are to be understood as being modified by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. An image display, comprising:
at least one organic light emitting diode (OLED) having a top surface;
a high index optical coupling layer in contact with the top surface, the high index optical coupling layer having a nanostructured exterior surface.

2. The image display of claim 1, wherein the nanostructured exterior surface is integral with the high index optical coupling layer.

3. The image display of claim 1, wherein the nanostructured exterior surface comprises a nanostructured transfer layer disposed on the high index optical coupling layer.

4. The image display of claim 1, wherein the nanostructured exterior surface includes selected nanostructured regions and adjacent planar regions.

5. The image display of claim 4, wherein at least one of the selected nanostructured regions is disposed over emissive regions of the OLED.

6. The image display of claim 1, wherein the optical coupling layer comprises a hybrid material.

7. The image display of claim 6, wherein the hybrid material comprises a nanoparticle-filled acrylate or a nanoparticle-filled silsesquioxane.

8. A method, comprising:
coating an optical coupling layer (OCL) precursor on a top surface of an OLED array, forming a planarized OCL precursor surface;
laminating a template film having a nanostructured surface onto the OCL precursor surface such that the OCL precursor at least partially fills the nanostructured surface;
polymerizing the OCL precursor to form a nanostructured OCL; and
removing the template film.

9-10. (canceled)

11. The method of claim 8, wherein the nanostructured surface of the template film comprises a release coating.

12. The method of claim 8, wherein the top surface of the OLED display comprises an adhesion promoting primer.

13. A method, comprising:
coating an optical coupling layer (OCL) precursor on a top surface of an OLED array, forming a planarized OCL precursor surface;
laminating a transfer film onto the OCL precursor surface, the transfer film comprising a nanostructured template film and a nanostructured transfer layer, such that a planar outer surface of the nanostructured transfer layer contacts the OCL precursor surface, wherein the transfer film includes an embedded nanostructured surface;
polymerizing the OCL precursor to form the OCL and bond the planar outer surface of the nanostructured transfer layer to the OCL; and
removing the nanostructured template film from the nanostructured transfer layer.

14-15. (canceled)

16. The method of claim 13, wherein the embedded nanostructured surface of the transfer film comprises a release coating.

17. The method of claim 13, wherein at least one of the top surface of the OLED display, the planarized OCL precursor, and the planar outer surface, comprises an adhesion promoting primer.

18. A method, comprising:
coating an optical coupling layer (OCL) precursor on a nanostructured surface of a template film;
laminating the template film onto a major surface of an OLED array such that the OCL precursor contacts the major surface;
polymerizing the OCL precursor to form the OCL and bond the OCL to the major surface of the OLED array; and
removing the template film.

19-20. (canceled)

21. The method of claim 18, wherein the nanostructured surface comprises a release coating.

22. The method of claim 18, wherein the top surface of the OLED display comprises an adhesion promoting primer.

23. A method, comprising:
forming a nanostructured layer on a nanostructured surface of a template film such that the nanostructured layer has a planar outer surface and an embedded nanostructured surface;
coating an optical coupling layer (OCL) precursor on the planar outer surface to form a transfer film;
laminating the transfer film onto a major surface of an OLED array such that the OCL precursor contacts the major surface;
polymerizing the OCL precursor to form the OCL and bond the OCL to the major surface of the OLED array; and
removing the template film from the nanostructured layer.

24-25. (canceled)

26. The method of claim 23, wherein the embedded nanostructured surface comprises a release coating.

27. The method of claim 23, wherein the top surface of the OLED display comprises an adhesion promoting primer.

28. A method, comprising:
coating an optical coupling layer (OCL) precursor on a top surface of an OLED array, forming a planarized OCL precursor surface;
laminating a template film having a nanostructured surface onto the planarized OCL precursor surface such that the OCL precursor at least partially fills the nanostructured surface;
polymerizing the OCL precursor in selected regions to form a patterned nanostructured OCL having unpolymerized regions;
removing the template film; and
polymerizing the unpolymerized regions.

29-30. (canceled)

31. The method of claim 28, wherein the nanostructured surface comprises a release coating.

32. The method of claim 28, wherein the top surface of the OLED display comprises an adhesion promoting primer.

33. The method of claim 28, further comprising reflowing the unpolymerized regions after removing the transfer film and before polymerizing the unpolymerized regions.

34. The method of claim 33, wherein reflowing comprises planarizing the unpolymerized regions by heating.

35. The method of claim 28, wherein polymerizing the OCL precursor in selected regions comprises self-registered photoexposure from at least one OLED pixel emission.

36. A method, comprising:
coating an optical coupling layer (OCL) precursor on a top surface of an OLED array, forming a planarized OCL precursor surface;
masking selected regions of the OCL precursor to prevent polymerization;
polymerizing the OCL precursor to form a patterned OCL having unpolymerized regions;
laminating a transfer film onto the patterned OCL such that a transfer layer of the transfer film contacts a major surface of the patterned OCL, wherein the transfer layer includes a planar outer surface and an embedded nanostructured surface;
removing the transfer film from the patterned OCL, leaving the transfer layer in the selected regions; and
polymerizing the unpolymerized regions of the patterned OCL to bond the planar outer transfer layer to the selected regions of the OCL.

37-38. (canceled)

39. The method of claim 36, wherein the embedded nanostructured surface comprises a release coating.

40. The method of claim 36, wherein the top surface of the OLED display comprises an adhesion promoting primer.

41. A method, comprising:
forming a transfer layer on a nanostructured surface of a transfer film such that the transfer layer has a planar outer surface and an embedded nanostructured surface;
coating an optical coupling layer (OCL) precursor on the planar outer surface;
masking selected regions of the OCL precursor to prevent polymerization;
polymerizing the OCL precursor to form a patterned OCL having unpolymerized transferable OCL regions;
laminating the transfer film onto a major surface of an OLED array such that the unpolymerized transferable OCL regions contact the major surface;
polymerizing the unpolymerized transferable OCL regions to form a bonded patterned nanostructured OCL on the major surface of the OLED array; and
removing the transfer film from the major surface of the OLED array, leaving the bonded patterned nanostructured OCL on the major surface of the OLED array.

42-43. (canceled)

44. The method of claim 41, wherein the embedded nanostructured surface comprises a release coating.

45. The method of claim 41, wherein the top surface of the OLED display comprises an adhesion promoting primer.
